(19) United States
(12) Patent Application Publication
(10) Pub. No.: US 2011/0114183 A1
(43) Pub. Date: May 19, 2011

(54) POLYMER COMPOUND AND ORGANIC PHOTOELECTRIC CONVERTER USING THE SAME

(75) Inventors: Yasunori Uetani, Tsukuba-shi (JP); Takanobu Noguchi, Tsukuba-shi (JP)

(73) Assignee: SUMITOMO CHEMICAL COMPANY, LIMITED, Chuo-ku, Tokyo (JP)

(21) Appl. No.: 12/738,041

(22) PCT Filed: Oct. 17, 2008
(86) PCT No.: PCT/JP2008/069286

§ 371 Date: Nov. 23, 2010

(30) Foreign Application Priority Data
Oct. 19, 2007 (JP) 2007-272239

(51) Int. Cl. H01L 51/46; C08G 75/06

(52) U.S. Cl. 136/263; 525/389

(57) ABSTRACT

A polymer compound comprising a repeating unit represented by the formula (1) and a repeating unit represented by the formula (2).

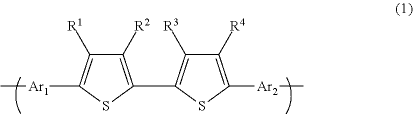

In the formula (1), Ar₁ and Ar₂ each independently represent an arylene group or a group represented by the following formula (3); R¹, R², R³, and R⁴ each independently represent a hydrogen atom, an alkyl group, an alkoxy group, or an aryl group; and a hydrogen atom contained in these groups may be substituted by a fluorine atom.

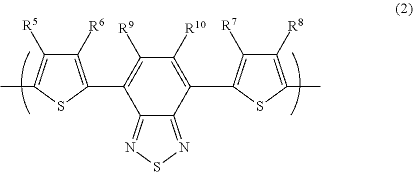

In the formula (2), R⁵, R⁶, R⁷, R⁸, R⁹, and R¹⁰ each independently represent a hydrogen atom, an alkyl group, an alkoxy group, or an aryl group; and a hydrogen atom contained in these groups may be substituted by a fluorine atom.

### TECHNICAL FIELD

The present invention relates to a polymer compound and an organic photoelectric converter using the same.

### BACKGROUND ART

In recent years, a study on use of an organic semiconductor material in an organic photoelectric converter such as an organic solar cell or an optical sensor has been actively carried out. As an example thereof, use of a fluorene copolymer made of the following repeating unit (M) and the following repeating unit (N) or a fluorene copolymer made of the following repeating unit (M) and the following repeating unit (O) in an organic solar cell is known (Non-patent Documents 1 and 2).

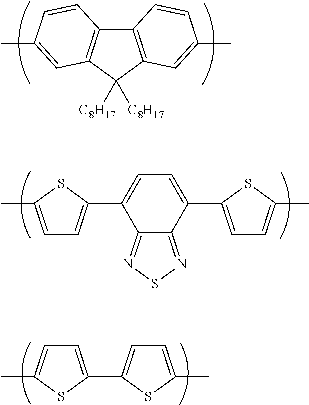

Repeating Unit (M) Repeating Unit (N) Repeating Unit (O)
[Non-patent Document 1] Applied Physics Letters Vol. 84, No. 10, 1653-1655 (2004)
[Non-patent Document 2] Chemical Review Vol. 107, 1324-1338 (2007)

### DISCLOSURE OF THE INVENTION

However, when the aforesaid fluorene copolymer is used in an organic photoelectric converter, the photoelectric conversion efficiency of the converter is not necessarily sufficient.

Therefore, an object of the present invention is to provide a polymer compound that imparts, when used in an organic photoelectric converter, excellent photoelectric conversion efficiency to the converter.

In a first aspect, the present invention provides a polymer compound containing a repeating unit represented by the formula (1) and a repeating unit represented by the formula (2):

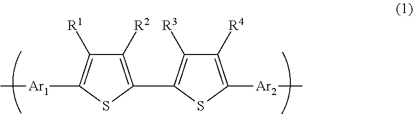

wherein Ar₁ and Ar₂ each independently represent an arylene group or a group represented by the following formula (3); R¹, R², R³, and R⁴ each independently represent a hydrogen atom, an alkyl group, an alkoxy group, or an aryl group; and a hydrogen atom contained in these groups may be substituted by a fluorine atom:

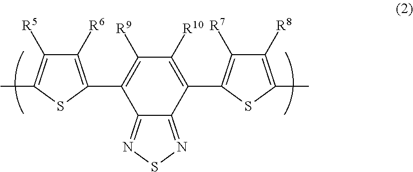

wherein R⁵, R⁶, R⁷, R⁸, R⁹, and R¹⁰ each independently represent a hydrogen atom, an alkyl group, an alkoxy group, or an aryl group; and a hydrogen atom contained in these groups may be substituted by a fluorine atom:

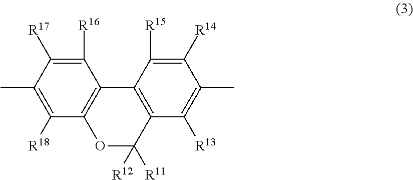

wherein R¹¹, R¹², R¹³, R¹⁴, R¹⁵, R¹⁶, R¹⁷, and R¹⁸ each independently represent a hydrogen atom, an alkyl group, an alkoxy group, or an aryl group; and a hydrogen atom contained in these groups may be substituted by a fluorine atom.

In a second aspect, the present invention provides the polymer compound wherein the arylene group is a group represented by the formula (4) or a group represented by the following formula (5):

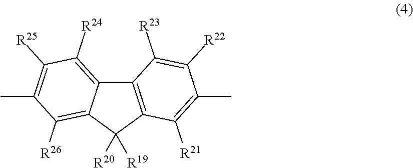

wherein R¹⁹, R²⁰, R²¹, R²², R²³, R²⁴, R²⁵, and R²⁶ each independently represent a hydrogen atom, an alkyl group, an alkoxy group, or an aryl group; and a hydrogen atom contained in these groups may be substituted by a fluorine atom:

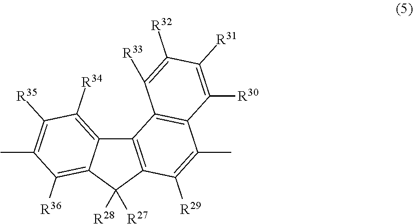

wherein R²⁷, R²⁸, R²⁹, R³⁰, R³¹, R³², R³³, R³⁴, R³⁵, and R³⁶ each independently represent a hydrogen atom, an alkyl group, an alkoxy group, or an aryl group; and a hydrogen atom contained in these groups may be substituted by a fluorine atom.

In a third aspect, the present invention provides an organic photoelectric converter having an organic layer containing the polymer compound of the present invention.

In a fourth aspect, the present invention provides an organic photoelectric converter having a pair of electrodes at least one of which is transparent or semitransparent, and a first organic layer containing the polymer compound of the present invention and a second organic layer containing an electron-donating compound disposed adjacent to the first organic layer between the electrodes.

In a fifth aspect, the present invention provides an organic photoelectric converter having a pair of electrodes at least one of which is transparent or semitransparent, and a first organic layer containing an electron-accepting compound and a second organic layer containing the polymer compound of the present invention disposed adjacent to the first organic layer between the electrodes.

In a sixth aspect, the present invention provides an organic photoelectric converter having a pair of electrodes at least one of which is transparent or semitransparent and an organic layer containing the polymer compound of the present invention and an electron-donating compound between the electrodes.

In a seventh aspect, the present invention provides an organic photoelectric converter having a pair of electrodes at least one of which is transparent or semitransparent and an organic layer containing an electron-accepting compound and the polymer compound of the present invention between the electrodes.

### MODES FOR CARRYING OUT THE INVENTION

### Polymer Compound

The polymer compound of the present invention contains a repeating unit represented by the formula (1) and a repeating unit represented by the formula (2).

In the formula (1), R¹, R², R³, and R⁴ each independently represent a hydrogen atom, an alkyl group, an alkoxy group, or an aryl group. A hydrogen atom contained in these groups may be substituted by a fluorine atom.

The alkyl group may be either linear or branched or may be cyclic, and typically has about 1 to 20 carbon atoms. The alkyl group may be, for example, a methyl group, an ethyl group, an n-propyl group, an i-propyl group, an n-butyl group, an i-butyl group, a t-butyl group, a s-butyl group, a 3-methylbutyl group, an n-pentyl group, an n-hexyl group, a 2-ethylhexyl group, an n-heptyl group, an n-octyl group, an n-nonyl group, an n-decyl group, a 3,7-dimethyloctyl group, an n-lauryl group, or the like. A hydrogen atom in the aforesaid alkyl group may be substituted by a fluorine atom. The alkyl group substituted by a fluorine atom may be, for example, a trifluoromethyl group, a pentafluoroethyl group, a perfluorobutyl group, a perfluorohexyl group, a perfluorooctyl group, or the like.

The alkyl group contained in the alkoxy group may be either linear or branched or may be cyclic. The alkoxy group typically has about 1 to 20 carbon atoms. The alkoxy group may be, for example, a methoxy group, an ethoxy group, an n-propyloxy group, an i-propyloxy group, an n-butoxy group, an i-butoxy group, an s-butoxy group, a t-butoxy group, an n-pentyloxy group, an n-hexyloxy group, a cyclohexyloxy group, an n-heptyloxy group, an n-octyloxy group, a 2-ethylhexyloxy group, an n-nonyloxy group, an n-decyloxy group, a 3,7-dimethyloctyloxy group, an n-lauryloxy group, or the like. A hydrogen atom in the aforesaid alkoxy group may be substituted by a fluorine atom. The alkoxy group substituted by a fluorine atom may be, for example, a trifluoromethoxy group, a pentafluoroethoxy group, a perfluorobutoxy group, a perfluorohexyl group, a perfluorooctyl group, or the like.

The aryl group is an atomic group obtained by removing one hydrogen atom from an aromatic hydrocarbon. The aryl groups include those having a benzene ring, those having a condensed ring, and those in which two or more of independent benzene rings or condensed rings are directly bonded or bonded via a divalent group such as a vinylene group. The aryl group has typically about 6 to 60, preferably 6 to 48 carbon atoms. The aforesaid aryl group may have a substituent. The substituent may be, for example, a linear or branched alkyl group having 1 to 20 carbon atoms, a cycloalkyl group having 1 to 20 carbon atoms, an alkoxy group containing a linear or branched alkyl group having 1 to 20 carbon atoms or a cycloalkyl group having 1 to 20 carbon atoms in the structure thereof, a group represented by the formula (10), or the like.

—O—(CH₂)_{g}—O—(CH₂)ₕ—CH₃ (10)

(In the formula (10), g represents an integer of 1 to 6, and h represents an integer of 0 to 5.)

The aryl group may be, for example, a phenyl group, a C₁-C₁₂ alkoxyphenyl group (“C₁-C₁₂” means that the group has 1 to 12 carbon atoms and the same applies hereafter as well), a C₁-C₁₂ alkylphenyl group, a 1-naphthyl group, a 2-naphthyl group, a 1-anthracenyl group, a 2-anthracenyl group, a 9-anthracenyl group, a pentafluorophenyl group, or the like, where a C₁-C₁₂ alkoxyphenyl group and a C₁-C₁₂ alkylphenyl group are preferable. The C₁-C₁₂ alkoxyphenyl group may be, for example, a methoxyphenyl group, an ethoxyphenyl group, an n-propyloxyphenyl group, an isopropyloxyphenyl group, an n-butoxyphenyl group, an isobutoxyphenyl group, an s-butoxyphenyl group, a t-butoxyphenyl group, an n-pentyloxyphenyl group, an n-hexyloxyphenyl group, a cyclohexyloxyphenyl group, an n-heptyloxyphenyl group, an n-octyloxyphenyl group, a 2-ethylhexyloxyphenyl group, an n-nonyloxyphenyl group, an n-decyloxyphenyl group, a 3,7-dimethyloctyloxyphenyl group, an n-lauryloxyphenyl group, or the like. The C₁-C₁₂ alkylphenyl group may be, for example, a methylphenyl group, an ethylphenyl group, a dimethylphenyl group, an n-propylphenyl group, a mesityl group, a methylethylphenyl group, an isopropylphenyl group, an n-butylphenyl group, an isobutylphenyl, an s-butylphenyl group, a t-butylphenyl group, an n-pentylphenyl group, an isoamylphenyl group, a hexylphenyl group, an n-heptylphenyl group, an n-octylphenyl group, an n-nonylphenyl group, an n-decylphenyl group, an n-dodecylphenyl group, or the like. A hydrogen atom in the aforesaid aryl group may be substituted by a fluorine atom.

In the formula (1), Ar₁ and Ar₂ each independently represent an arylene group or a group represented by the formula (3).

Here, the arylene group is an atomic group obtained by removing two hydrogen atoms from an aromatic hydrocarbon. The arylene groups include those having a benzene ring, those having a condensed ring, and those in which two or more of independent benzene rings or condensed rings are directly bonded or bonded via a divalent group such as a vinylene group. The arylene group may have a substituent. The substituent may be, for example, a linear or branched alkyl group having 1 to 20 carbon atoms, a cycloalkyl group having 1 to 20 carbon atoms, an alkoxy group containing a linear or branched alkyl group having 1 to 20 carbon atoms or a cycloalkyl group having 1 to 20 carbon atoms in the structure thereof, or the like. The part excluding the substituents in the arylene group has typically about 6 to 60, preferably 6 to 20 carbon atoms. Also, the total number of carbon atoms in the arylene group including the substituents is typically about 6 to 100.

The arylene group may be, for example, a phenylene group, a naphthalenediyl group, an anthracene-diyl group, a biphenyl-diyl group, a terphenyl-diyl group, a fluorenediyl group, a benzofluorenediyl group, or the like.

Among the arylene groups, the group represented by the formula (4) or the group represented by the formula (5) is preferable from the viewpoint of conversion efficiency when the polymer compound is used in an organic photoelectric converter.

The alkyl groups represented by R¹⁹ to R²⁶ in the formula (4) may be, for example, the same groups as those in the case of R¹.

The alkoxy groups represented by R¹⁹ to R²⁶ in the formula (4) may be, for example, the same groups as those in the case of R¹.

The aryl groups represented by R¹⁹ to R²⁶ in the formula (4) may be, for example, the same groups as those in the case of R¹.

From the viewpoint of solubility of the polymer compound of the present invention in an organic solvent, both of R¹⁹ and R²⁰ in the formula (4) are preferably an alkyl group, an alkoxy group, or an aryl group, and more preferably an alkyl group or an aryl group.

The group represented by the formula (4) may be, for example, one of the following groups.

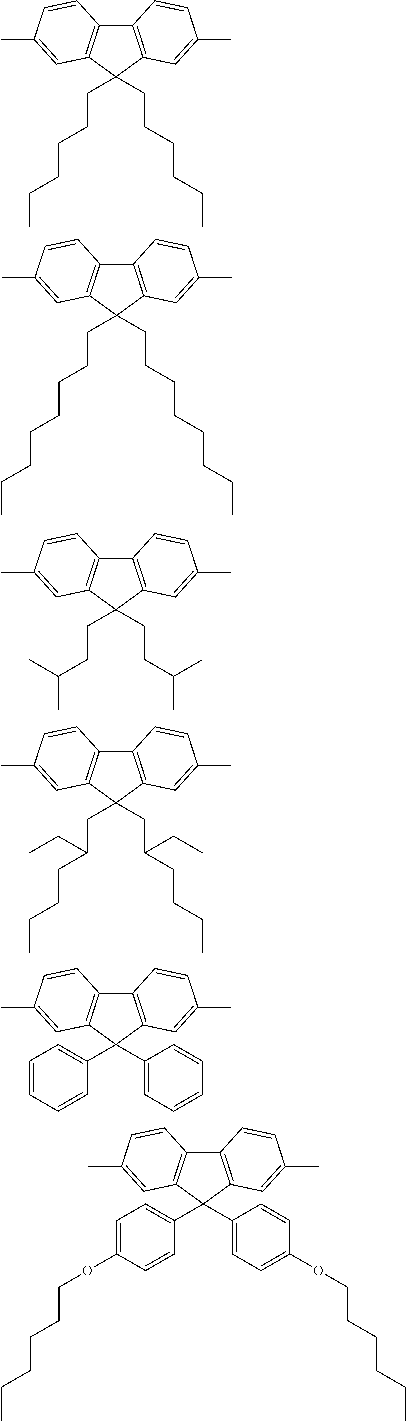

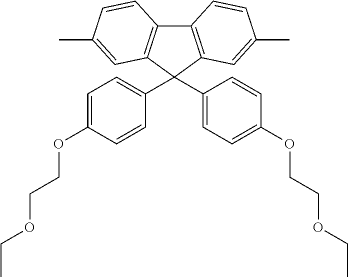

The alkyl groups represented by R²⁷ to R³⁶ in the formula (5) may be, for example, the same groups as those in the case of R¹.

The alkoxy groups represented by R²⁷ to R³⁶ in the formula (5) may be, for example, the same groups as those in the case of R¹.

The aryl groups represented by R²⁷ to R³⁶ in the formula (5) may be, for example, the same groups as those in the case of R¹.

From the viewpoint of solubility of the polymer compound of the present invention in an organic solvent, both of R²⁷ and R²⁸ in the formula (5) are preferably an alkyl group, an alkoxy group, or an aryl group, and more preferably an alkyl group or an aryl group.

The group represented by the formula (5) may be, for example, one of the following groups.

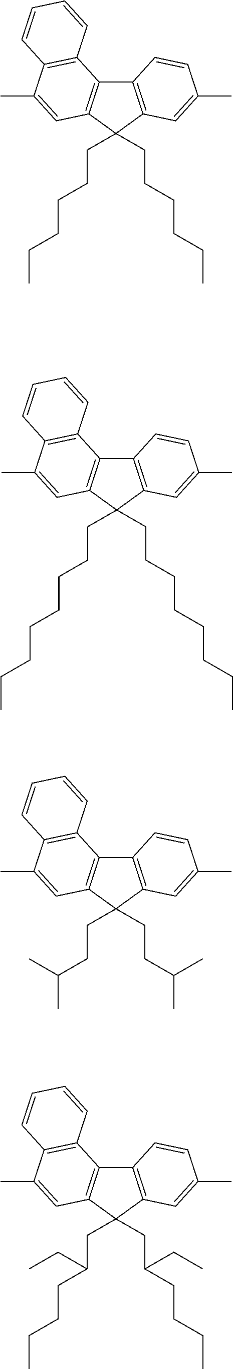

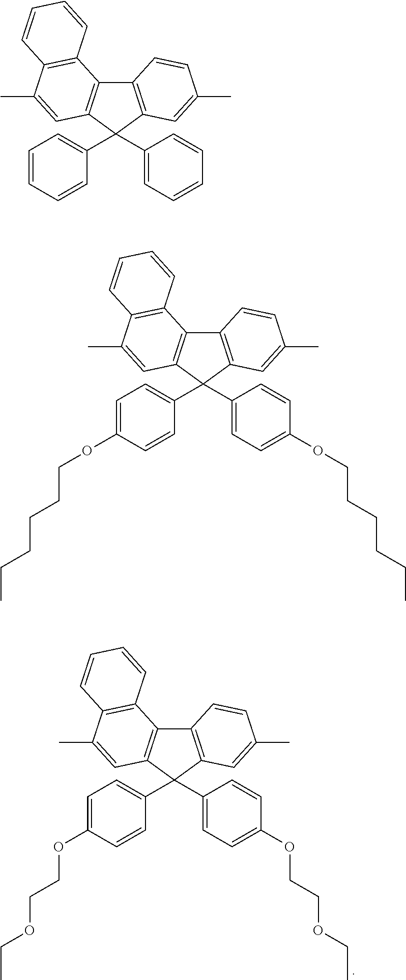

Ar₁ and Ar₂ in the aforesaid formula (1) may be a group represented by the aforesaid formula (3). In the formula (3), R¹¹, R¹², R¹³, R¹⁴, R¹⁵, R¹⁶, R¹⁷, and R¹⁸ each independently represent a hydrogen atom, an alkyl group, an alkoxy group, or an aryl group. A hydrogen atom contained in these groups may be substituted by a fluorine atom.

The alkyl groups represented by R¹¹ to R¹⁸ in the formula (3) may be, for example, the same groups as those in the case of R¹.

The alkoxy groups represented by R¹¹ to R¹⁸ in the formula (3) may be, for example, the same groups as those in the case of R¹.

The aryl groups represented by R¹¹ to R¹⁸ in the formula (3) may be, for example, the same groups as those in the case of R¹.

From the viewpoint of solubility of the polymer compound of the present invention in an organic solvent, both of R¹¹ and R¹² in the formula (3) are preferably an alkyl group, an alkoxy group, or an aryl group, and more preferably an alkyl group or an aryl group.

The group represented by the formula (3) may be, for example, one of the following groups.

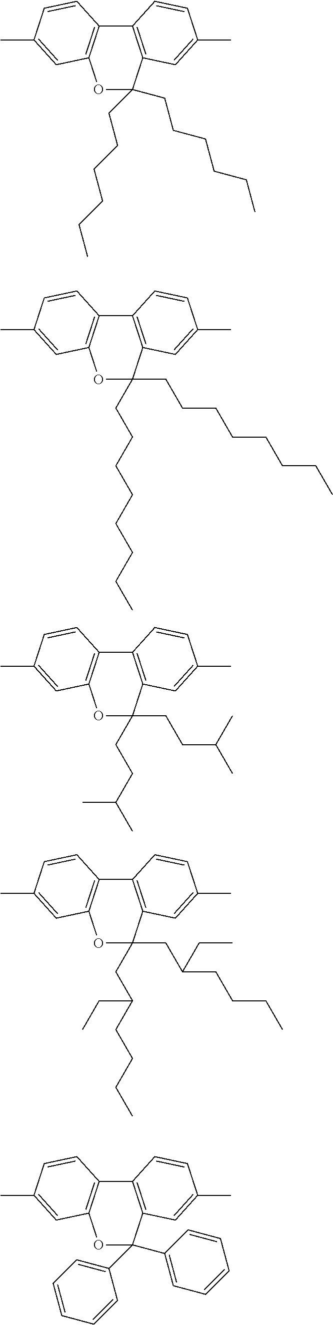

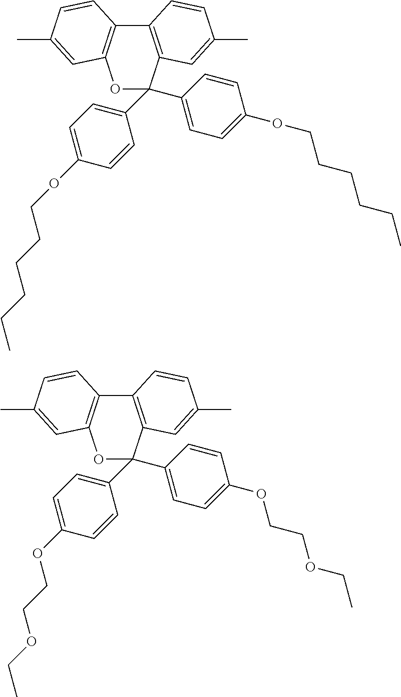

In the aforesaid formula (1), a combination of Ar₁ and Ar₂ may be, for example, a combination in which Ar₁ and Ar₂ are each a group represented by the aforesaid formula (4), a combination in which Ar₁ and Ar₂ are each a group represented by the aforesaid formula (5), a combination in which Ar₁ and Ar₂ are each a group represented by the aforesaid formula (3), a combination in which Ar₁ is a group represented by the formula (4) and Ar₂ is a group represented by the formula (5), a combination in which Ar₁ is a group represented by the formula (4) and Ar₂ is a group represented by the formula (3), a combination in which Ar₁ is a group represented by the formula (5) and Ar₂ is a group represented by the formula (3), or the like.

From the viewpoint of luminance efficiency of an organic photoelectric converter using the polymer compound of the present invention, the formula (1) is preferably a repeating unit represented by the formula (9).

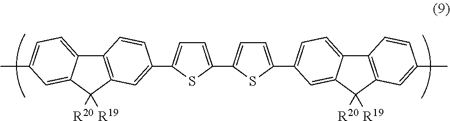

In the formula (9), R¹⁹ and R²⁰ represent the same meanings as described above. The plurality of groups R¹⁹ and R²⁰ may each be the same or different.

In addition to the repeating unit represented by the formula (1), the polymer compound of the present invention contains a repeating unit represented by the aforesaid formula (2). In the formula (2), R⁵, R⁶, R⁷, R⁸, R⁹, and R¹⁰ each independently represent a hydrogen atom, an alkyl group, an alkoxy group, or an aryl group. A hydrogen atom contained in these groups may be substituted by a fluorine atom.

The alkyl groups represented by R⁵ to R¹⁰ in the formula (2) may be, for example, the same groups as those in the case of R¹.

The alkoxy groups represented by R⁵ to R¹⁰ in the formula (2) may be, for example, the same groups as those in the case of R¹.

The aryl groups represented by R⁵ to R¹⁰ in the formula (2) may be, for example, the same groups as those in the case of R¹.

The repeating unit represented by the formula (2) may be, for example, one of the following repeating units.

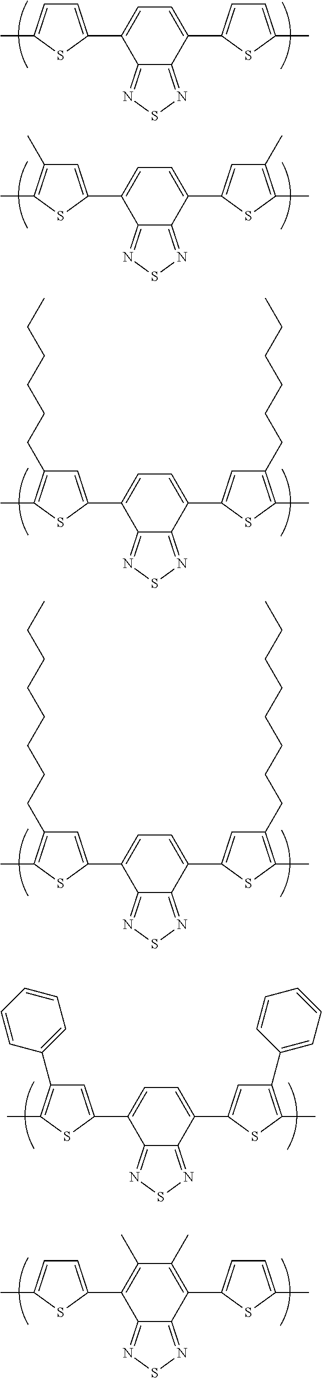

The polymer compound of the present invention may contain a repeating unit other than the repeating unit represented by the aforesaid formula (1) and the repeating unit represented by the aforesaid formula (2). The repeating unit other than the repeating units represented by the formula (1) and formula (2) may be, for example, an arylene group, a divalent aromatic amine group, a divalent heterocyclic group, or the like.

The arylene group may be, for example, the same group as those in the case of Ar₁.

The divalent aromatic amine group may be, for example, a group represented by one of the formulas (11-1) to (11-8).

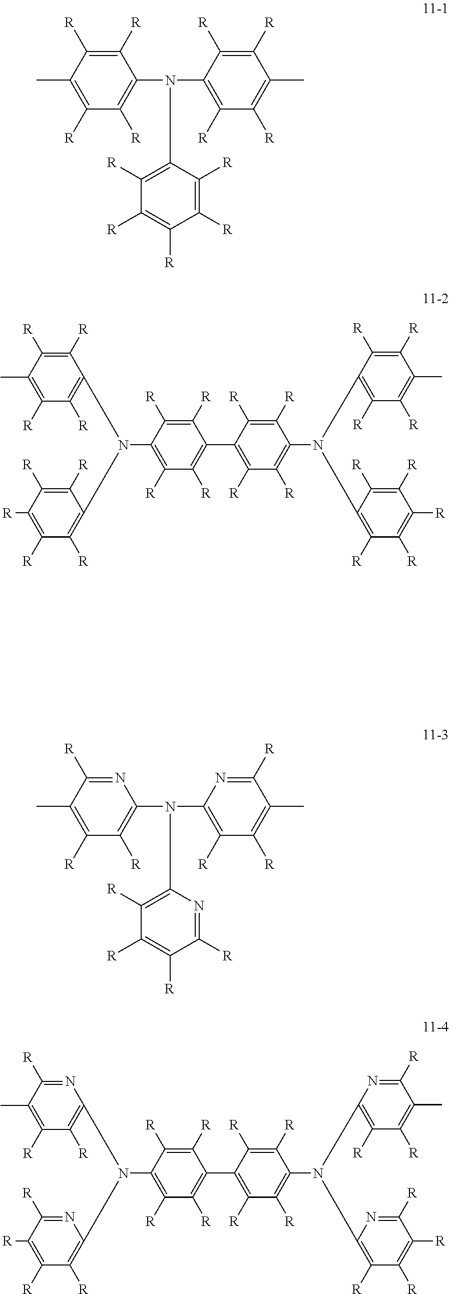

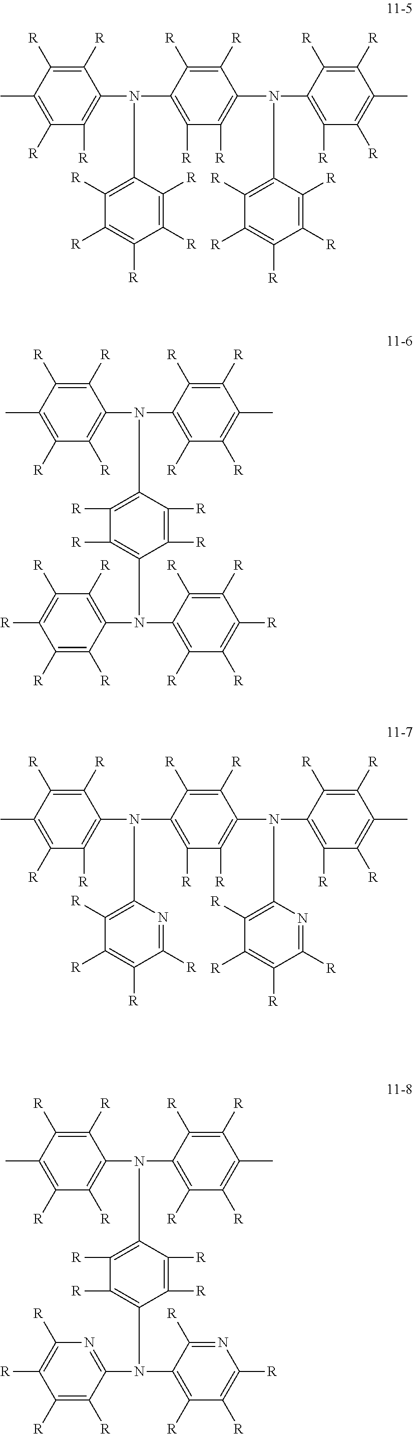

In the formulas (11-1) to (11-8), R represents a hydrogen atom, an alkyl group, an alkoxy group, or an aryl group. The plurality of R may be the same or different.

The alkyl group, alkoxy group, or aryl group represented by R in the formulas (11-1) to (11-8) may be, for example, the same group as those in the case of R¹.

The divalent heterocyclic group is a residual atomic group obtained by removing two hydrogen atoms from a heterocyclic compound, and the group may have a substituent.

Here, the heterocyclic compound refers to those in which the elements constituting the ring include a heteroatom such as oxygen, sulfur, nitrogen, phosphorus, boron, or arsenic in the ring besides the carbon atoms among the organic compounds having a ring structure. Among the divalent heterocyclic groups, divalent aromatic heterocyclic groups are preferable. The part excluding the substituents in the divalent heterocyclic group typically has about 3 to 60 carbon atoms. Also, the total number of carbon atoms in the divalent heterocyclic group including the substituents is typically about 3 to 100.

The divalent heterocyclic group may be, for example, the following ones.

Divalent heterocyclic groups containing nitrogen as a heteroatom: a pyridine-diyl group (the following formulas 101 to 106), a diazaphenylene group (the following formulas 107 to 110), a quinolinediyl group (the following formulas 111 to 125), a quinoxalinediyl group (the following formulas 126 to 130), an acridinediyl group (the following formulas 131 to 134), a bipyridyldiyl group (the following formulas 135 to 137), and a phenanthrolinediyl group (the following formulas 138 to 140).

Five-membered heterocyclic groups containing oxygen, silicon, nitrogen, sulfur, selenium, boron, phosphorus, or the like as a heteroatom (the following formulas 141 to 145).

Five-membered condensed heterocyclic groups containing oxygen, silicon, nitrogen, selenium, or the like as a heteroatom (the following formulas 146 to 157).

A group represented by the aforesaid formula (3).

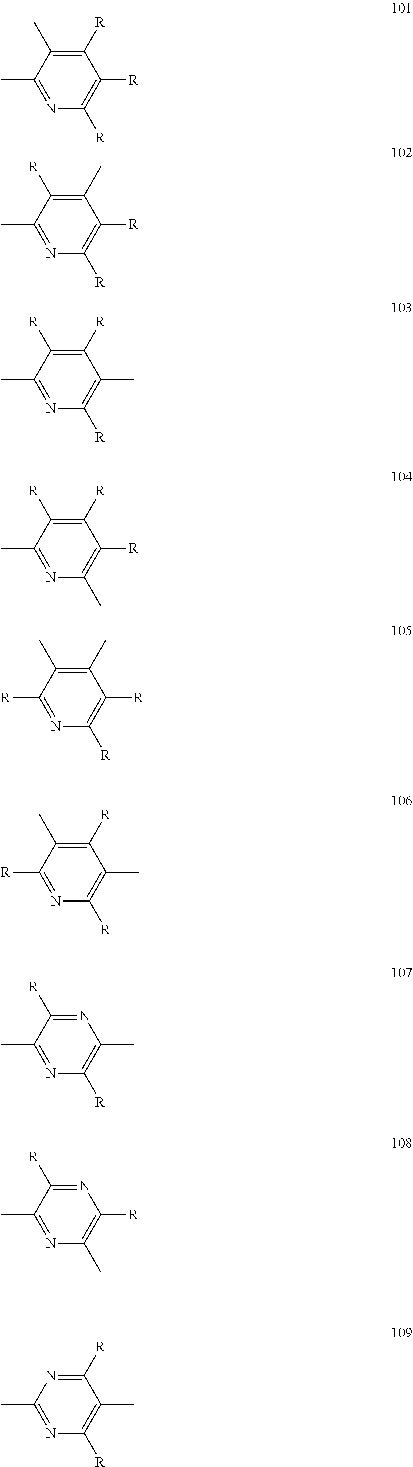

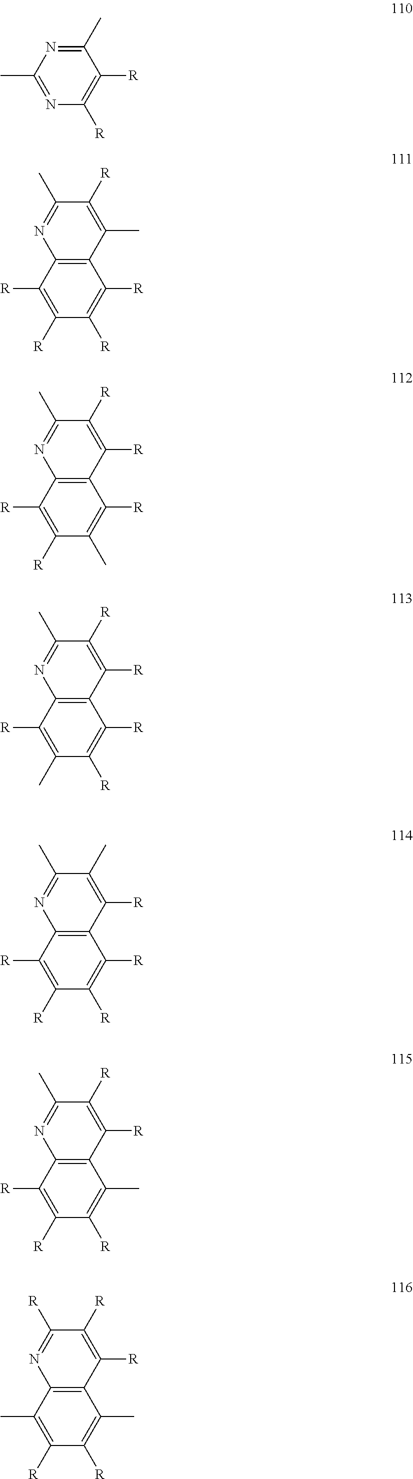

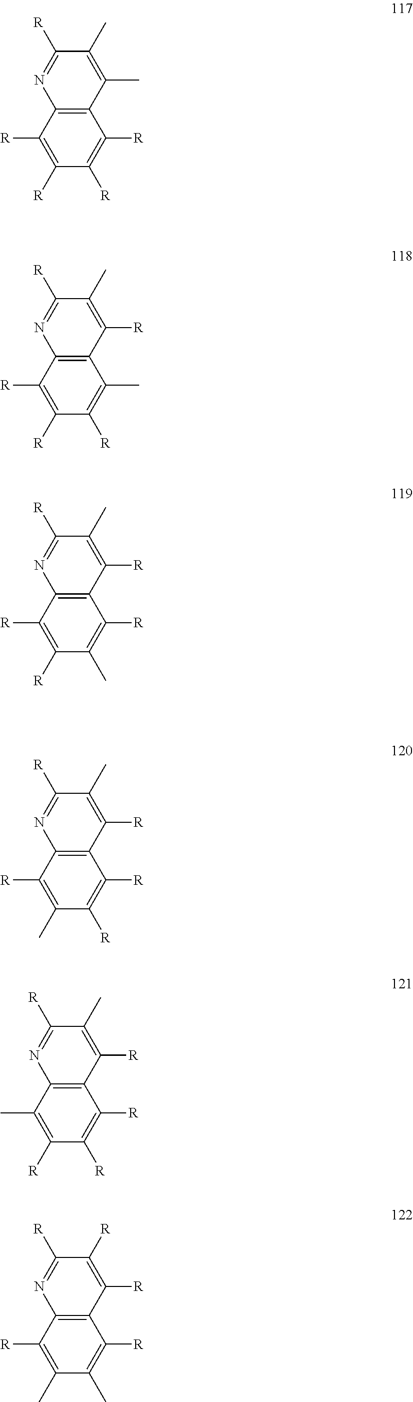

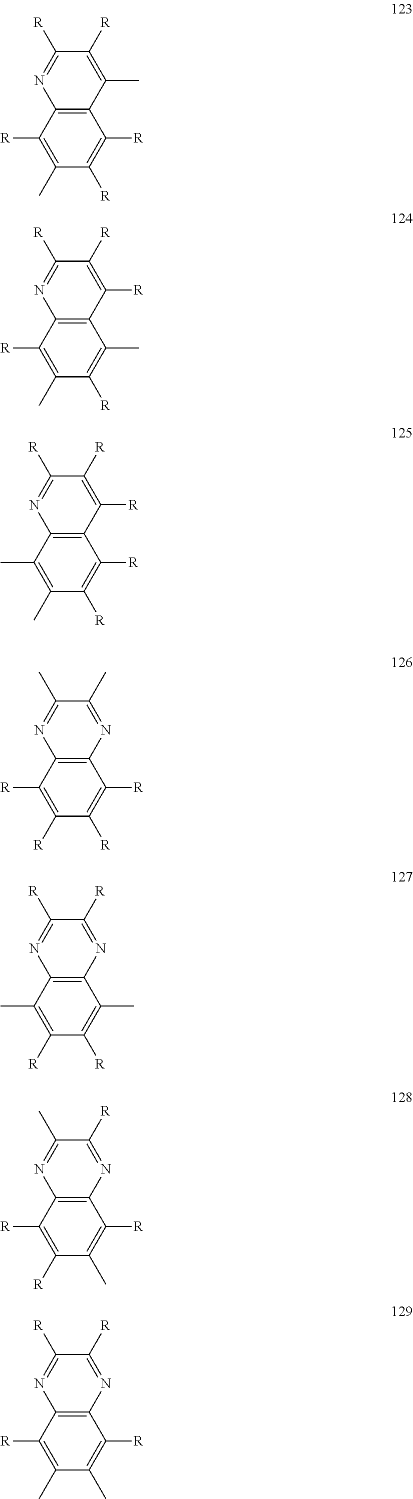

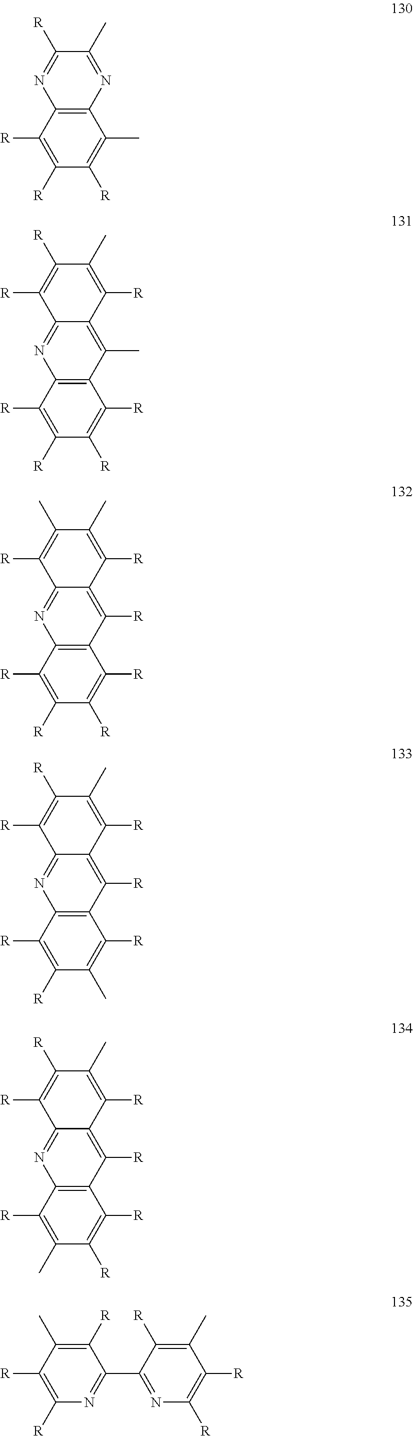

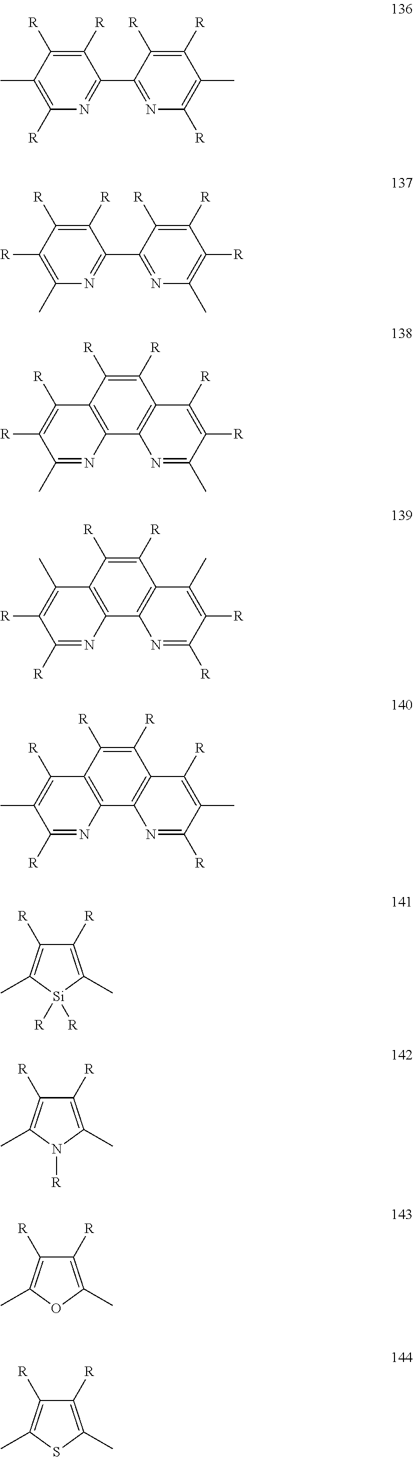

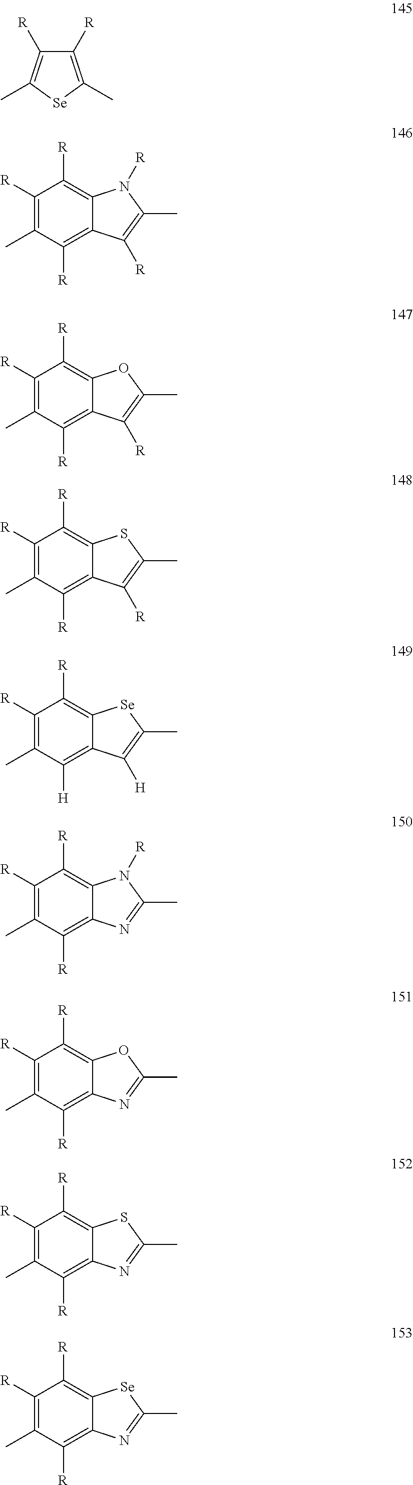

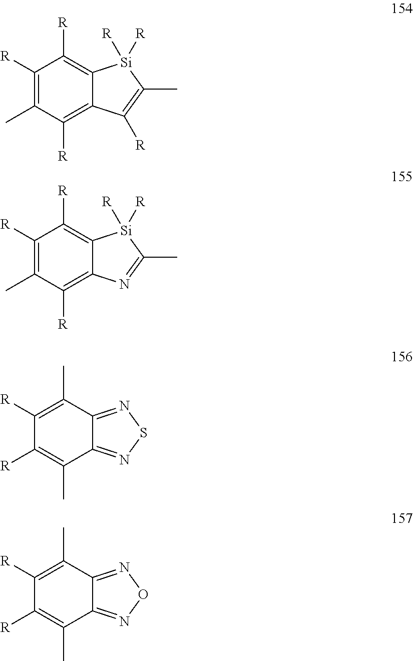

(R in the formulas 101 to 157 represents the same meaning as the aforesaid R.)

The repeating unit that the polymer compound of the present invention may contain other than the repeating unit represented by the aforesaid formula (1) and the repeating unit represented by the aforesaid formula (2) is preferably a fluorenediyl group, a benzofluorenediyl group, a thiophenediyl group, a 6H-dibenzo[b,d]pyran-3,8-diyl group, or the like.

Assuming that the sum of the repeating units represented by the formula (1) and the repeating units represented by the formula (2) is 100, the polymer compound of the present invention contains 1 to 99, preferably 10 to 90, repeating units represented by the formula (1), and contains 99 to 1, preferably 90 to 10, repeating units represented by the formula (2).

The polymer compound of the present invention may contain a block, and an example thereof is a block including a block having a repeating unit represented by the formula (1).

The block may be a block having one or more kinds of repeating units selected from the group consisting of a repeating unit represented by the formula (6), a repeating unit represented by the formula (7), and a repeating unit represented by the formula (8).

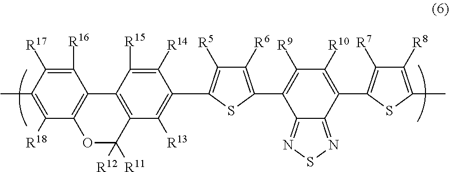

(In the formula (6), R⁵, R⁶, R⁷, R⁸, R⁹, R¹⁰, R¹¹, R¹², R¹³, R¹⁴, R¹⁵, R¹⁶, R¹⁷, and R¹⁸ represent the same meanings as described above.)

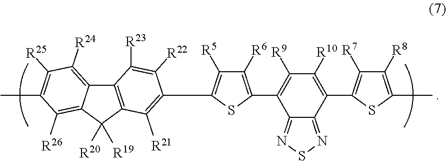

(In the formula (7), R⁵, R⁶, R⁷, R⁸, R⁹, R¹⁰, R¹⁹, R²⁰, R²¹, R²², R²³, R²⁴, R²⁵, and R²⁶ represent the same meanings as described above.)

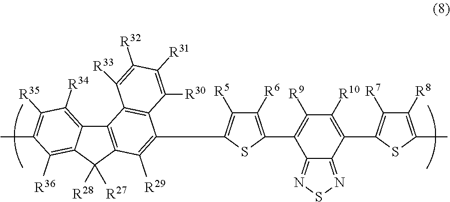

(In the formula (8), R⁵, R⁶, R⁷, R⁸, R⁹, R¹⁰, R²⁷, R²⁸, R²⁹, R³⁰, R³¹, R³², R³³, R³⁴, R³⁵, and R³⁶ represent the same meanings as described above.)

The repeating unit represented by the formula (6) may be, for example, one of the following repeating units.

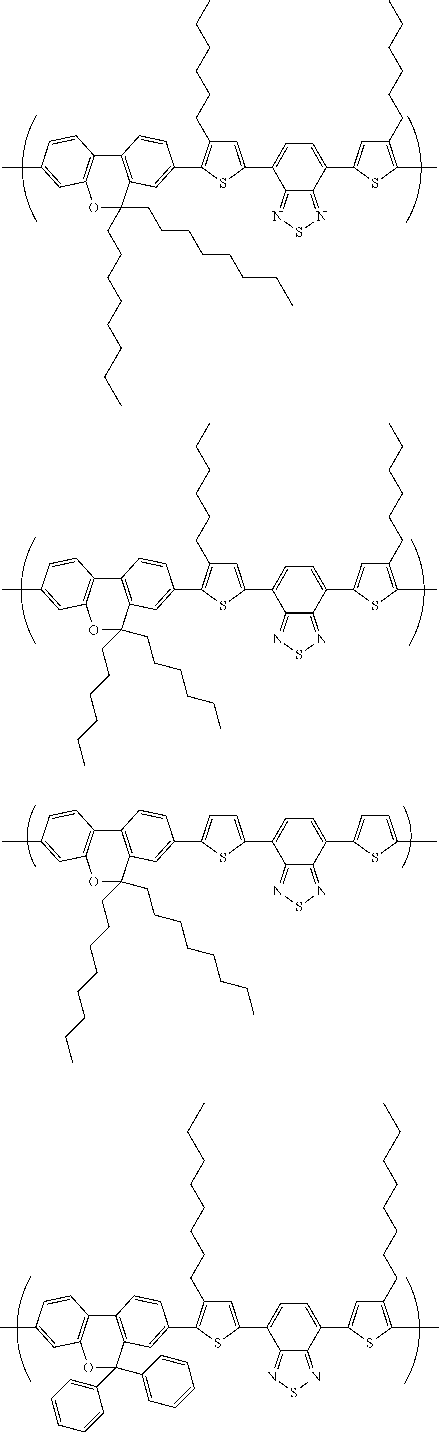

The repeating unit represented by the formula (7) may be, for example, one of the following repeating units.

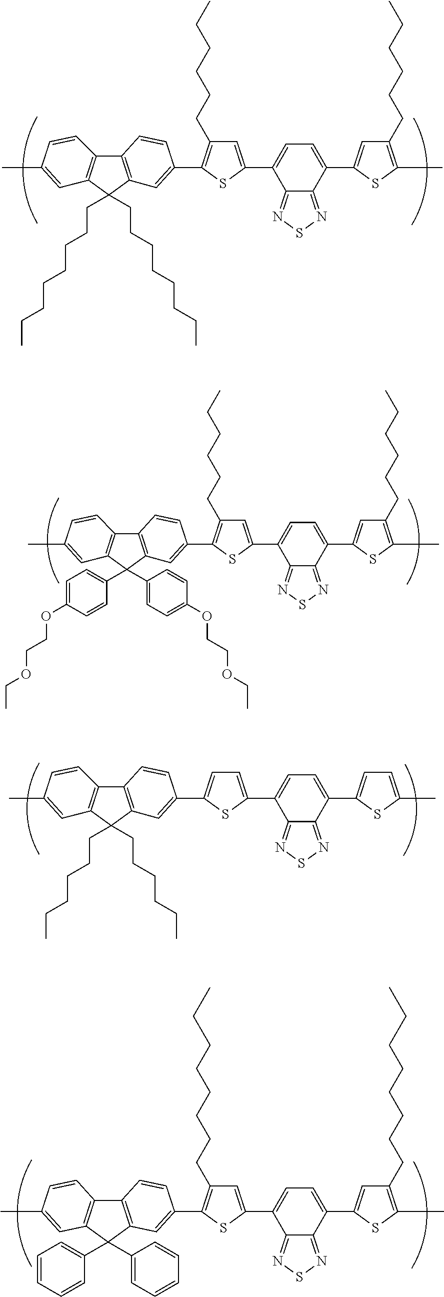

The repeating unit represented by the formula (8) may be, for example, one of the following repeating units.

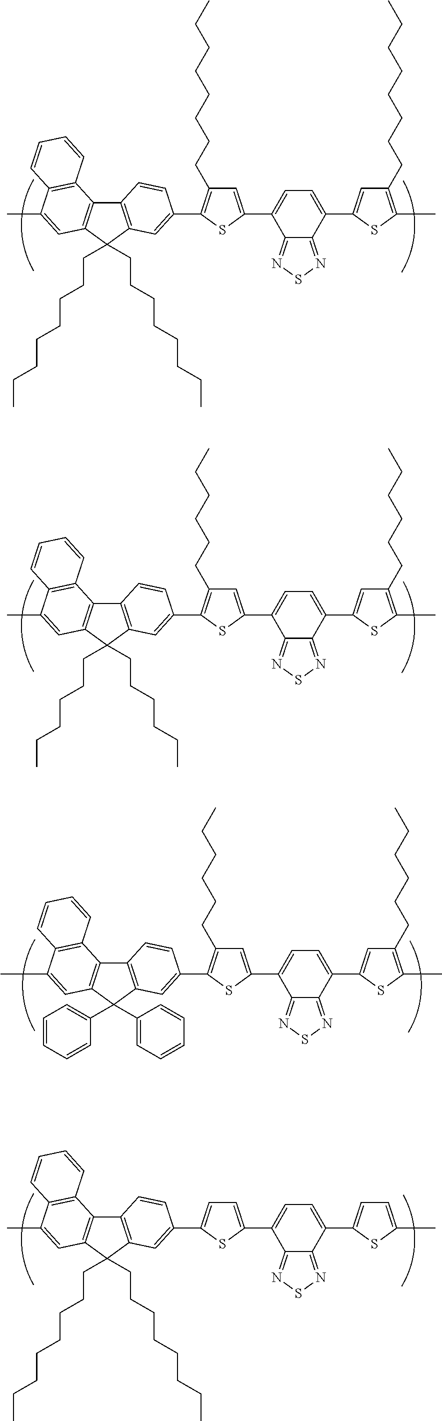

When the polymer compound of the present invention contains a block, the block may be, for example, a block made of a repeating unit represented by the formula (1), a block made of a repeating unit represented by the formula (2), a block made of a repeating unit represented by the formula (1) and a repeating unit other than the repeating unit represented by the formula (1), a block made of a repeating unit represented by the formula (2) and a repeating unit other than the repeating unit represented by the formula (2), or the like. Assuming that the repeating unit represented by the formula (1) is A, that the repeating unit represented by the formula (2) is B, and that the repeating unit other than the repeating unit represented by the formula (1) and the repeating unit represented by the formula (2) is C, a chain arrangement of the blocks contained in the polymer compound of the present invention may be, for example,

Aₖ-block-Bₘ,

Aₖ-block-(BC)ₘ,

(AC)ₖ-block-Bₘ,

(AC)ₖ-block-(BC)ₘ,

(AC)ₖ-block-(BC)ₘ-block-Cₙ,

or the like. Here, in the chain arrangement, k, m, and n each represent the number of repeating units. Also, when a plurality of C are present, the plurality of C may be the same or different.

When the polymer compound of the present invention contains a block having a repeating unit represented by the formula (1), the number-average molecular weight of the block as converted in terms of polystyrene is preferably 1×10³ to 1×10⁵, more preferably 1×10⁴ to 1×10⁵, from the viewpoint of photoelectric conversion efficiency characteristics of the converter and the solubility. The weight-average molecular weight as converted in terms of polystyrene is preferably 1×10³ to 1×10⁵, more preferably 1×10⁴ to 1×10⁵.

When the polymer compound of the present invention contains a block having one or more kinds of repeating units selected from the group consisting of a repeating unit represented by the aforesaid formula (6), a repeating unit represented by the aforesaid formula (7), and a repeating unit represented by the aforesaid formula (8), the number-average molecular weight of the block as converted in terms of polystyrene is preferably 1×10³ to 1×10⁵, more preferably 1×10⁴ to 1×10⁵, from the viewpoint of photoelectric conversion efficiency characteristics of the converter and the solubility. The weight-average molecular weight as converted in terms of polystyrene is preferably 1×10³ to 1×10⁵, more preferably 1×10⁴ to 1×10⁵.

The number-average molecular weight of the polymer compound of the present invention as converted in terms of polystyrene is preferably 1×10³ to 1×10⁸, more preferably 1×10⁴ to 1×10⁷, from the viewpoint of photoelectric conversion efficiency characteristics of the converter and the solubility in an organic solvent. The weight-average molecular weight as converted in terms of polystyrene is preferably 1×10³ to 1×10⁸, more preferably 1×10⁴ to 1×10⁷.

In the present invention, the number-average molecular weight and the weight-average molecular weight as converted in terms of polystyrene can be determined by gel permeation chromatography (GPC).

The polymer compound of the present invention may be a random-, alternate-, block-, or graft-copolymer, or may be a polymer having an intermediate structure lying therebetween, for example, a random copolymer endowed with block characteristics. The block is typically constituted of two or more repeating units, preferably four or more repeating units.

The polymer compounds of the present invention include those having a branched main chain and having three or more terminal end parts, as well as dendrimers.

Also, when a group having a polymerization activity remains as it is at a terminal end of the polymer compound, there is a possibility that the photoelectric conversion efficiency may decrease when the polymer compound is made into a converter. Therefore, the terminal end of the polymer compound may be protected by a stable protective group. The protective group is preferably one having a conjugate bond that is continuous to the conjugate structure of the main chain, and may be, for example, one having a structure such that the polymer compound is bonded to an aryl group or a heterocyclic group serving as a protective group via a carbon-carbon bond. The protective group may be, for example, a substituent disclosed in the chemical formula 10 of Japanese Patent Application Laid-open (JP-A) No. 09-45478.

A good solvent to the polymer compound of the present invention may be, for example, chloroform, methylene chloride, dichloroethane, tetrahydrofuran, toluene, xylene, mesitylene, tetralin, decalin, n-butylbenzene, or the like. Typically, although depending on the structure and the molecular weight of the polymer compound, 0.1 wt % or more of the polymer compound can be dissolved in these solvents.

### Method of Producing Polymer Compound

Next, a method of producing the polymer compound of the present invention will be described.

The polymer compound of the present invention can be produced, for example, by dissolving a compound having two substituents all or part of which are eliminated at the time of condensation polymerization, which will be a monomer (source material compound), in an organic solvent as necessary, and allowing the resultant to react at a temperature equal to or higher than the melting point and equal to or lower than the boiling point of the organic solvent with use of, for example, an alkali or a suitable catalyst. In producing the polymer compound of the present invention, it is possible to employ known methods such as those disclosed in “Organic Reactions”, vol. 14, pp. 270-490, John Wiley & Sons, Inc., 1965, “Organic Syntheses”, Collective Volume VI, pp. 407-411, John Wiley & Sons, Inc., 1988, Chem. Rev., vol. 95, p. 2457 (1995), J. Organomet. Chem., vol. 576, p. 147 (1999), Macromol. Chem., Macromol. Symp., vol. 12, p. 229 (1987), and the like.

In producing the polymer compound of the present invention, a condensation reaction with known source material compounds can be used. The method of producing the polymer compound of the present invention may be, for example, a method of polymerizing a relevant monomer by Suzuki coupling reaction, a method of polymerization by Grignard reaction, a method of polymerization by a zero-valent nickel complex, a method of polymerization by an oxidant such as FeCl₃, a method of electrochemical oxidation polymerization, a method by decomposition of an intermediate polymer having suitable leaving groups, or the like. Among these, the method of polymerization by Suzuki coupling reaction, the method of polymerization by Grignard reaction, and the method of polymerization by a zero-valent nickel complex are preferable because structural control is facilitated.

When the polymer compound of the present invention is a block polymer, a method of synthesizing the block polymer may be, for example, a method of synthesizing a first block having a high molecular weight and adding a monomer constituting a second block to this to perform polymerization, a method of synthesizing a first block having a high molecular weight and a second block having a high molecular weight in advance and linking these, or the like.

In the method of producing the polymer compound of the present invention, the substituents all or part of which are eliminated at the time of condensation polymerization may be, for example, a halogen atom, an alkylsulfo group, an arylsulfo group, an arylalkylsulfo group, a boric acid ester group, a sulfoniummethyl group, a phosphoniummethyl group, a phosphonatemethyl group, a monohalogenated methyl group, —B(OH)₂, a formyl group, a cyano group, a vinyl group, or the like.

The alkylsulfo group may be, for example, a methanesulfo group, an ethanesulfo group, a trifluoromethanesulfo group, or the like. The arylsulfo group may be, for example, a benzenesulfo group, a p-toluenesulfo group, or the like. The arylalkylsulfo group may be, for example, a benzylsulfo group or the like.

The boric acid ester group may be, for example, a group represented by one of the following formulas.

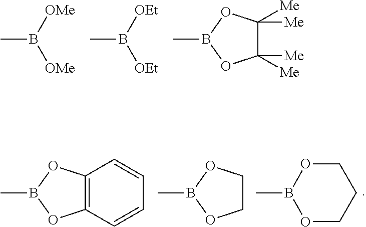

(In the formulas, Me represents a methyl group, and Et represents an ethyl group.)

The sulfoniummethyl group may be, for example, a group represented by one of the following formulas.

—CH₂S⁺Me₂X⁻, —CH₂S⁺Ph₂X⁻

(In the formulas, X represents a halogen atom, Me represents a methyl group, and Ph represents a phenyl group.)

The phosphoniummethyl group may be, for example, a group represented by the following formula.

—CH₂P⁺Ph₃X⁻

(In the formula, X represents a halogen atom and Ph represents a phenyl group.)

The phosphonatemethyl group may be, for example, a group represented by the following formula.

—CH₂PO(OR′)₂

(In the formula, R′ represents an alkyl group, an aryl group, or an arylalkyl group.)

The monohalogenated methyl group may be, for example, a fluorinated methyl group, a chlorinated methyl group, a brominated methyl group, or an iodinated methyl group.

A substituent preferable as the substituents all or part of which are eliminated at the time of condensation polymerization may differ depending on the kind of polymerization reaction. However, when a zero-valent nickel complex (Ni(0) complex) is used such as in Yamamoto coupling reaction, the preferable substituent may be, for example, a halogen atom, an alkylsulfo group, an arylsulfo group, an arylalkylsulfo group, or the like. Also, when a nickel catalyst or a palladium catalyst is used such as in Suzuki coupling reaction, the preferable substituent may be, for example, an alkylsulfo group, a halogen atom, a boric acid ester group, —B(OH)₂, or the like.

Among the methods of producing the polymer compound of the present invention, a production method is preferable such that the substituents all or part of which are eliminated at the time of condensation polymerization are independently selected from a halogen atom, an alkylsulfo group, an arylsulfo group, and an arylalkylsulfo group, and condensation polymerization is carried out in the presence of a zero-valent nickel complex. The source material compound may be, for example, a dihalogenated compound, a bis(alkylsulfonate) compound, a bis(arylsulfonate) compound, a bis(arylalkylsulfonate) compound, a halogen-alkylsulfonate compound, a halogen-arylsulfonate compound, a halogen-arylalkylsulfonate compound, an alkylsulfonate-arylsulfonate compound, an alkylsulfonate-arylalkylsulfonate compound, an arylsulfonate-arylalkylsulfonate compound, or the like. A method can be exemplified such that, among these, by using, for example, a halogen-alkylsulfonate compound, a halogen-arylsulfonate compound, a halogen-arylalkylsulfonate compound, an alkylsulfonate-arylsulfonate compound, an alkylsulfonate-arylalkylsulfonate compound, or an arylsulfonate-arylalkylsulfonate compound as a source material compound, a polymer compound with controlled sequence can be produced.

Also, among the methods of producing the polymer compound of the present invention, a production method is preferable such that the substituents all or part of which are eliminated at the time of condensation polymerization are independently selected from a halogen atom, an alkylsulfo group, an arylsulfo group, an arylalkylsulfo group, a boric acid group (—B(OH)₂), or a boric acid ester group; the ratio K/J of the sum (K) of the molar numbers of the boric acid groups and the boric acid ester groups to the sum (J) of the molar numbers of the halogen atoms, the alkylsulfo groups, the arylsulfo groups, and the arylalkylsulfo groups that the whole source material compounds have is substantially 1 (typically within a range of 0.7 to 1.2); and condensation polymerization is carried out using a nickel catalyst or a palladium catalyst. A combination of the source material compounds may be, for example, a combination of one kind or two or more kinds of dihalogenated compounds, bis(alkylsulfonate) compounds, bis(arylsulfonate) compounds, or bis(arylalkylsulfonate) compounds and one kind or two or more kinds of diboric acid compounds or diboric acid ester compounds, or the like. Also, the source material compounds may be, for example, a halogenated-boric acid compound, a halogenated-boric acid ester compound, an alkylsulfonate-boric acid compound, an alkylsulfonate-boric acid ester compound, an arylsulfonate-boric acid compound, an arylsulfonate-boric acid ester compound, an arylalkylsulfonate-boric acid compound, an arylalkylsulfonate-boric acid ester compound, or the like. A method can be exemplified such that, among these, by using, for example, a halogenated-boric acid compound, a halogenated-boric acid ester compound, an alkylsulfonate-boric acid compound, an alkylsulfonate-boric acid ester compound, an arylsulfonate-boric acid compound, an arylsulfonate-boric acid ester compound, an arylalkylsulfonate-boric acid compound, or an arylalkylsulfonate-boric acid ester compound as a source material compound, a polymer compound with controlled sequence can be produced.

The solvent used for reaction may differ depending on the compounds to be used and the reaction. Typically, however, it is preferable that a deoxygenation treatment is sufficiently carried out in order to suppress the side reaction. The reaction is preferably allowed to proceed in an inert gas atmosphere. Also, in a similar manner, the solvent to be used in the reaction is preferably subjected to a dehydration treatment.

However, in the case of reaction in a two-phase system with water such as in the Suzuki coupling reaction, this may not apply.

The solvent may be, for example, a saturated hydrocarbon such as pentane, hexane, heptane, octane, cyclohexane, or decalin, an aromatic hydrocarbon such as benzene, toluene, ethylbenzene, n-butylbenzene, xylene, or tetralin, a halogenated saturated hydrocarbon such as carbon tetrachloride, chloroform, dichloromethane, chlorobutane, bromobutane, chloropentane, bromopentane, chlorohexane, bromohexane, chlorocyclohexane, or bromocyclohexane, a halogenated aromatic hydrocarbon such as chlorobenzene, dichlorobenzene, or trichlorobenzene, an alcohol such as methanol, ethanol, propanol, isopropanol, butanol, or t-butyl alcohol, a carboxylic acid such as formic acid, acetic acid, or propionic acid, an ether such as dimethyl ether, diethyl ether, methyl-t-butyl ether, tetrahydrofuran, tetrahydropyran, or dioxane, an amine such as trimethylamine, triethylamine, N,N,N′,N′-tetramethylethylenediamine, or pyridine, or an amide such as N,N-dimethylformamide, N,N-dimethylacetamide, N,N-diethylacetamide, or N-methylmorpholine oxide, or the like. These solvents may be used either alone or by mixing. Among these, ethers are preferable, and tetrahydrofuran and diethyl ether are further preferable.

In order to promote the reaction, an alkali or a suitable catalyst is suitably added. These may be selected in accordance with the reaction to be used. The alkali or catalyst is preferably one that is sufficiently dissolved in the solvent to be used for the reaction. The alkali may be, for example, an inorganic base such as potassium carbonate or sodium carbonate; an organic base such as triethylamine; or an inorganic salt such as cesium fluoride. The catalyst may be, for example, palladium [tetrakis(triphenylphosphine)], palladium acetate, or the like. As a method of mixing the alkali or catalyst, a method can be exemplified such that a solution of the alkali or catalyst is added slowly while stirring the reaction liquid in an inert atmosphere such as argon or nitrogen, or conversely the reaction liquid is slowly added into a solution of the alkali or catalyst.

When the polymer compound of the present invention is used in a photoelectric converter such as an organic solar cell, the purity thereof affects the performance of the converter, such as the photoelectric conversion efficiency. Therefore, the polymerization is preferably carried out after purifying the monomer before being subjected to the polymerization by a method such as distillation, sublimation purification, or recrystallization. Also, after the polymerization, a purifying treatment such as classification by reprecipitation purification or chromatography is preferably carried out.

### Organic Photoelectric Converter

The organic photoelectric converter of the present invention has a pair of electrodes at least one of which is transparent or semitransparent, and a layer containing the polymer compound of the present invention between the electrodes. The polymer compound of the present invention can be used either as an electron-accepting compound or as an electron-donating compound; and, the polymer compound is preferably used as an electron-donating compound.

The organic photoelectric converter of the present invention may be, for example,

1. an organic photoelectric converter having a pair of electrodes, and a first organic layer containing the polymer compound of the present invention and a second organic layer containing an electron-donating compound disposed adjacent to the first organic layer between the electrodes;
2. an organic photoelectric converter having a pair of electrodes, and a first organic layer containing an electron-accepting compound and a second organic layer containing the polymer compound of the present invention disposed adjacent to the first organic layer between the electrodes;
3. an organic photoelectric converter having a pair of electrodes and at least one organic layer containing the polymer compound of the present invention and an electron-donating compound between the electrodes;
4. an organic photoelectric converter having a pair of electrodes and an organic layer containing an electron-accepting compound and the polymer compound of the present invention between the electrodes;
5. an organic photoelectric converter having a pair of electrodes and at least one organic layer containing an electron-accepting compound and the polymer compound of the present invention disposed between the electrodes, wherein the electron-accepting compound is a fullerene derivative; or the like.

Also, in the organic photoelectric converter of the aforesaid 5., the ratio of the fullerene derivative in the organic layer containing the fullerene derivative and the polymer compound of the present invention is preferably 10 to 1000 parts by weight, more preferably 50 to 500 parts by weight, relative to 100 parts by weight of the polymer compound of the present invention.

As the organic photoelectric converter of the present invention, the aforesaid 3., the aforesaid 4., or the aforesaid 5. is preferable, and the aforesaid 5. is more preferable from the viewpoint of containing more heterojunction interface. Also, in the organic photoelectric converter of the present invention, an additive layer may be disposed between at least one of the electrodes and the organic layer in the converter. The additive layer may be, for example, an electric charge transporting layer that transports holes or electrons.

When the polymer compound of the present invention is used as an electron donor, an electron acceptor suitably used in the organic photoelectric converter is such that the HOMO energy of the electron acceptor is higher than the HOMO energy of the polymer compound, and the LUMO energy of the electron acceptor is higher than the LUMO energy of the polymer compound. Also, when the polymer compound of the present invention is used as an electron acceptor, an electron donor suitably used in the organic photoelectric converter is such that the HOMO energy of the electron donor is lower than the HOMO energy of the polymer compound, and the LUMO energy of the electron donor is lower than the LUMO energy of the polymer compound.

The organic photoelectric converter of the present invention is typically formed on a substrate. This substrate may be one that does not change at the time of forming the electrodes and forming the organic layer. A material of the substrate may be, for example, glass, plastics, a polymer film, silicon, or the like. In the case of an opaque substrate, the opposing electrode (that is, the electrode that is farther from the substrate) is preferably transparent or semitransparent.

The aforesaid transparent or semitransparent electrode material may be, for example, a metal oxide film having an electric conductivity, a semitransparent metal thin film, or the like. Specifically as the electrode material, a film (NESA or the like) that is fabricated by using electrically conductive glass made of indium oxide, zinc oxide, tin oxide, or indium.tin.oxide (ITO), indium.zinc.oxide, or the like, which are composites of these, gold, platinum, silver, copper, and the like are used, where ITO, indium.zinc.oxide, and tin oxide are preferable. A method of fabricating the electrodes may be, for example, the vacuum vapor deposition method, the sputtering method, the ion plating method, the plating method, or the like. Also, as the electrode material, an organic transparent conductive film made of polyaniline or a derivative thereof, polythiophene or a derivative thereof, or the like may be used. Further, as the electrode material, a metal, a conductive polymer, or the like can be used, and preferably one of the pair of electrodes is made of a material having a smaller work function. For example, a metal such as lithium, sodium, potassium, rubidium, cesium, magnesium, calcium, strontium, barium, aluminum, scandium, vanadium, zinc, yttrium, indium, cerium, samarium, europium, terbium, or ytterbium, an alloy of two or more of these, or an alloy of one or more of these and one or more of gold, silver, platinum, copper, manganese, titanium, cobalt, nickel, tungsten, and tin, graphite, a graphite interlayer compound, or the like is used. The alloy may be, for example, a magnesium-silver alloy, a magnesium-indium alloy, a magnesium-aluminum alloy, an indium-silver alloy, a lithium-aluminum alloy, a lithium-magnesium alloy, a lithium-indium alloy, a calcium-aluminum alloy, or the like.

As a material used in the electric charge transporting layer, that is, a hole transporting layer or an electron transporting layer, serving as the aforesaid additive layer, an electron-donating compound or an electron-accepting compound to be described later can be used, respectively.

As a material used in the buffer layer serving as the additive layer, a halide or oxide of an alkali metal or alkali earth metal such as lithium fluoride can be used. Also, fine particles of inorganic semiconductors such as titanium oxide can be used.

As the aforesaid organic layer (organic layer containing the polymer compound of the present invention) in the organic photoelectric converter of the present invention, an organic thin film containing the polymer compound of the present invention can be used, for example.

The aforesaid organic thin film typically has a film thickness of 1 nm to 100 μm, preferably 2 nm to 1000 nm, more preferably 5 nm to 500 nm, and still more preferably 20 nm to 200 nm.

The aforesaid organic thin film may contain either one kind of the polymer compound of the present invention alone or two or more kinds of them in combination. Also, in order to enhance the hole transportation property of the organic thin film, a low-molecular-weight compound and/or a polymer other than the polymer compound of the present invention can be mixed in the aforesaid organic thin film as the electron-donating compound and/or the electron-accepting compound.

The aforesaid electron-donating compound may be, for example, a pyrazoline derivative, an arylamine derivative, a stilbene derivative, a triphenyldiamine derivative, oligothiophene or a derivative thereof, polyvinylcarbazole or a derivative thereof, polysilane or a derivative thereof, a polysiloxane derivative having an aromatic amine in the side chain or the main chain, polyaniline or a derivative thereof, polythiophene or a derivative thereof, polypyrrole or a derivative thereof, polyphenylenevinylene or a derivatives thereof, polythienylenevinylene or a derivative thereof, or the like, besides the polymer compound of the present invention.

The aforesaid electron-accepting compound may be, for example, an oxadiazole derivative, anthraquinodimethane or a derivative thereof, benzoquinone or a derivative thereof, naphthoquinone or a derivative thereof, anthraquinone or a derivative thereof, tetracyanoanthraquinodimethane or a derivative thereof, a fluorenone derivative, diphenyldicyanoethylene or a derivative thereof, a diphenoquinone derivative, a metal complex of 8-hydroxyquinoline or a derivative thereof, polyquinoline or a derivative thereof, polyquinoxaline or a derivative thereof, polyfluorene or a derivative thereof, a fullerene such as C₆₀ or a derivative thereof, a phenanthrene derivative such as Bathocuproine, or the like, besides the polymer compound of the present invention. Among these, a fullerene and a derivative thereof are preferable.

The fullerenes include, for example, C₆₀, C₇₀, carbon nanotubes, and derivatives thereof. Derivatives of fullerene may be, for example, the following ones.

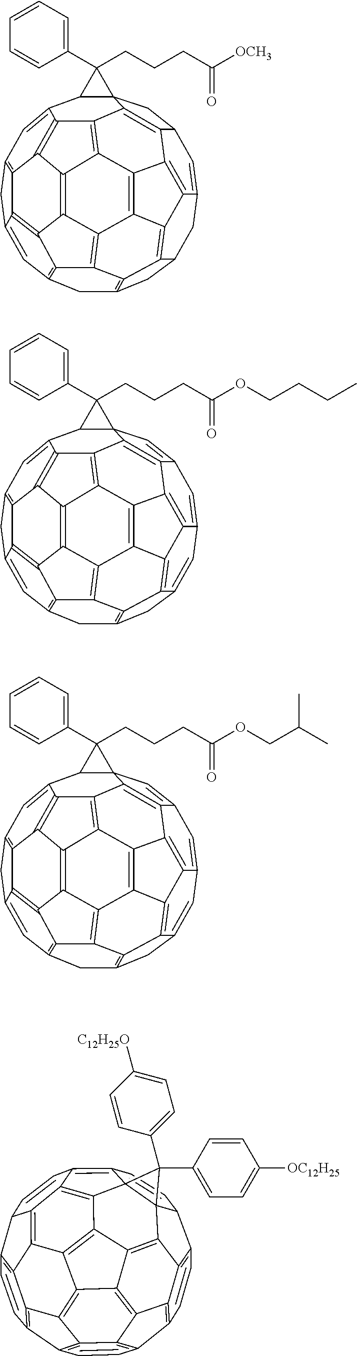

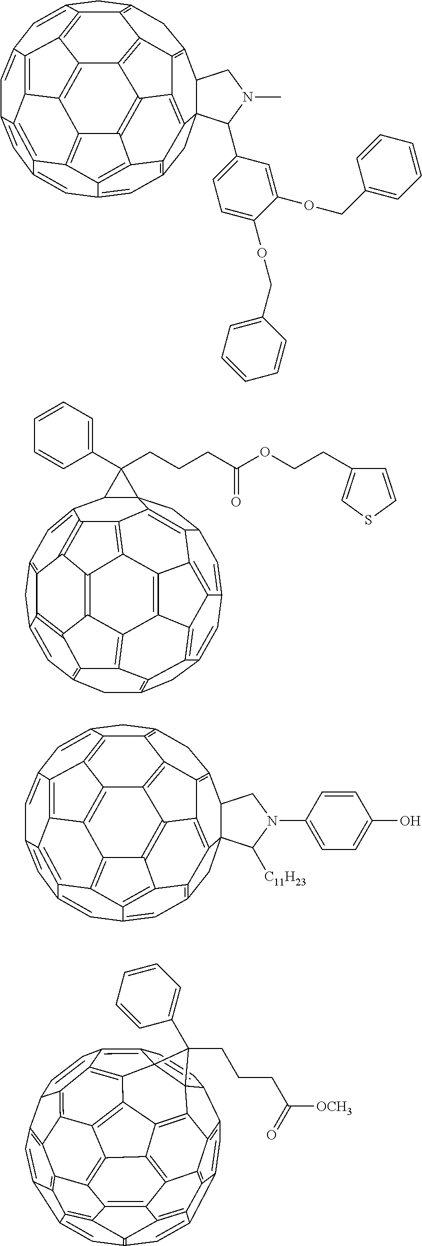

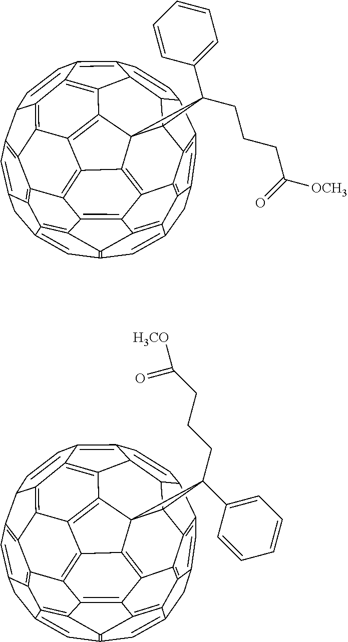

### Method of Producing Organic Thin Film

The method of producing the organic thin film is not particularly limited, and may be, for example, a method of forming a film from a solution containing the polymer compound of the present invention. Further, the thin film may be formed by the vacuum vapor deposition method.

The solvent used for forming a film from the solution is not particularly limited as long as the solvent can dissolve the polymer compound of the present invention. This solvent may be, for example, an unsaturated hydrocarbon solvent such as toluene, xylene, mesitylene, tetralin, decalin, bicyclohexyl, n-butylbenzene, sec-butylbenzene, or tert-butylbenzene, a halogenated saturated hydrocarbon solvent such as carbon tetrachloride, chloroform, dichloromethane, dichloroethane, chlorobutane, bromobutane, chloropentane, bromopentane, chlorohexane, bromohexane, chlorocyclohexane, or bromocyclohexane, a halogenated unsaturated hydrocarbon solvent such as chlorobenzene, dichlorobenzene, or trichlorobenzene, an ether solvent such as tetrahydrofuran or tetrahydropyran, or the like. The polymer compound of the present invention can be dissolved at an amount of 0.1 wt % or more in the aforesaid solvent.

For forming the film from the solution, an application method such as the spin coating method, the casting method, the microgravure coating method, the gravure coating method, the bar coating method, the roll coating method, the wirebar coating method, the dip coating method, the spray coating method, the screen printing method, the flexo printing method, the offset printing method, the inkjet printing method, the dispenser printing method, the nozzle coating method, or the capillary coating method, can be used. The spin coating method, the flexo printing method, the inkjet printing method, and the dispenser printing method are preferable.

### Usage of Converter

In the organic photoelectric converter, a photoelectromotive force is generated between the electrodes by radiation of light such as solar light from the transparent or semitransparent electrodes, whereby the organic photoelectric converter can be operated as an organic thin film solar cell. By integrating a plurality of organic thin film solar cells, the organic photoelectric converter can also be used as an organic thin film solar cell module.

Also, by radiation of light from the transparent or semitransparent electrode in a state in which a voltage is applied between the electrodes, a photocurrent flows, whereby the organic photoelectric converter can be operated as an organic optical sensor. By integrating a plurality of organic optical sensors, the organic photoelectric converter can also be used as an organic image sensor.

### EXAMPLES

Hereafter, examples will be shown in order to describe the present invention in a further greater detail; however, the present invention is not limited to these alone.

In the following examples, the number-average molecular weight and the weight-average molecular weight of the polymer as converted in terms of polystyrene were determined by using a GPC (trade name: LC-10Avp) manufactured by Shimadzu Corporation or a GPC (trade name: PL-GPC2000) manufactured by GPC Laboratory. In the case of measuring the average molecular weight by using the GPC manufactured by Shimadzu Corporation, 50 μL of a solution obtained by dissolving the polymer in tetrahydrofuran so as to attain a concentration of about 0.5 wt % was injected into the GPC. Tetrahydrofuran was used as a mobile phase of the GPC, and that was allowed to flow at a flow rate of 0.6 mL/minute. As the column of the GPC, two cylinders of TSKgel SuperHM-H (manufactured by Tosoh Corporation) and one cylinder of TSKgel SuperH2000 (manufactured by Tosoh Corporation) were connected in series for use. As a detector of the GPC, a differential refractive index detector (manufactured by Shimadzu Corporation, trade name: RID-10A) was used. In the case of measuring the average molecular weight by using the GPC manufactured by GPC Laboratory, a solution obtained by dissolving the polymer in o-dichlorobenzene so as to attain a concentration of about 1 wt % was used as a measurement sample. As a mobile phase of the GPC, o-dichlorobenzene was used and that was allowed to flow at a flow rate of 1 mL/minute at a measurement temperature of 140° C. As the column, three cylinders of PLGEL 10 μm MIXED-B (manufactured by PL Laboratory) were connected in series for use.

### Example 1

### Synthesis of Polymer Compound 1

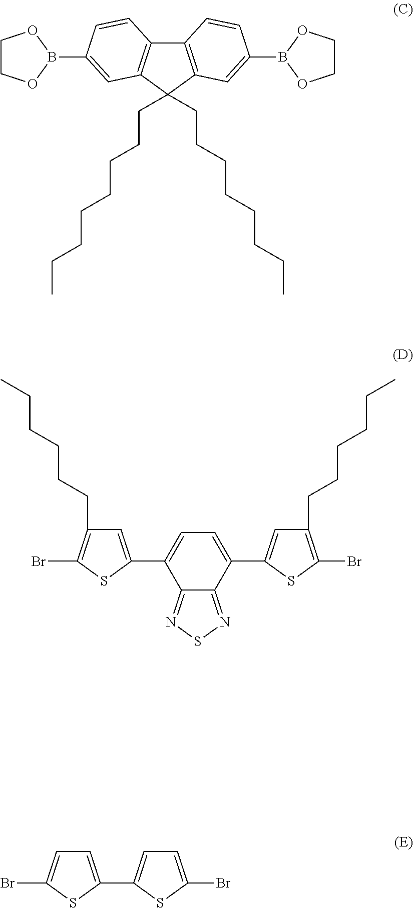

Into a 200 ml separable flask, 0.65 g of methyltrioctylammonium chloride (trade name: aliquat336, manufactured by Aldrich, CH₃N[(CH₂)₇CH₃]₃Cl, density 0.884 g/ml, 25° C., trade name of Henkel Corporation), 1.1276 g of the compound (C), and 0.8194 g of the compound (E) were put, and replacement with nitrogen was carried out. Into this, 25 ml of toluene that had been degassed by bubbling with argon gas in advance was added and, after stirring for dissolution, the solution was further degassed by bubbling with argon gas for 30 minutes. Subsequently, the flask containing this solution was immersed into a bath and, after the temperature thereof was raised to 85° C., 1.6 mg of palladium acetate and 4.8 mg of tris-o-methoxyphenylphosphine were added into the solution. Then, while the temperature of the bath was being raised up to 105° C., 6.8 ml of a 17.5% aqueous solution of sodium carbonate was dropwise added over 10 minutes. After dropwise addition, the solution was stirred for 2 hours at a bath temperature of 105° C., and the reaction solution was cooled to room temperature. In the reaction solution, a polymer containing a repeating unit represented by the formula (G) is contained.

The polymer contains the formula (G) as a repeating unit.

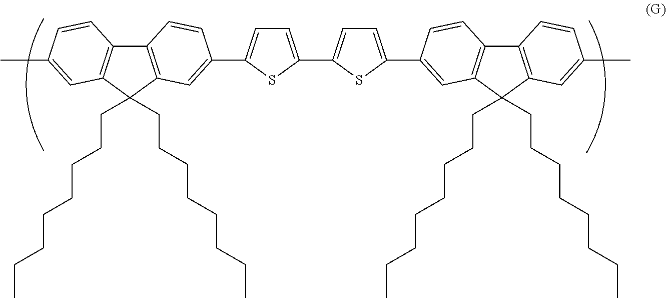

Next, 1.5386 g of the compound (C) and 1.5669 g of the compound (D) were added into the reaction solution. Into this, 25 ml of toluene that had been degassed by bubbling with argon gas in advance was added and, after stirring for dissolution, the solution was further degassed by bubbling with argon gas for 40 minutes. Into this solution, 1.3 mg of palladium acetate and 5.6 mg of tris-o-methoxyphenylphosphine were added. Then, while the temperature of the bath was being raised up to 105° C., 6.8 ml of a 17.5% aqueous solution of sodium carbonate was dropwise added over 10 minutes. After dropwise addition, the solution was stirred for 2 hours at a bath temperature of 105° C. After stirring, 50 ml of toluene that had been degassed by bubbling with argon gas in advance, 2 mg of palladium acetate, 7.5 mg of tris-o-methoxyphenylphosphine, and 0.306 g of phenylboric acid were added and stirred for about 9 hours at a bath temperature of 105° C. After an aqueous layer was removed from the reaction liquid, an aqueous solution obtained by dissolving 3.1 g of sodium N,N-diethyldithiocarbamate into 30 ml of water was added and stirred for 2 hours at a bath temperature of 85° C. Subsequently, 200 ml of toluene was added into this, and the reaction liquid was separated. After the organic phase was washed twice with 65 ml of water, twice with 65 ml of 3% acetic acid water, and twice with 65 ml of water, the resultant was dropwise added into 1500 ml of methanol so as to reprecipitate the polymer. After the precipitated polymer was filtered and dried under reduced pressure, the polymer was dissolved in 300 ml of toluene and passed through a silica gel-alumina column. The obtained toluene solution was dropwise added into 2500 ml of methanol so as to reprecipitate the polymer. The precipitated polymer was filtered and dried under reduced pressure to obtain 2.93 g of the polymer compound 1. The weight-average molecular weight of the obtained polymer compound 1 as converted in terms of polystyrene was 333,000, and the number-average molecular weight was 122,000.

The polymer compound 1 has a block containing a repeating unit represented by the formula (G) and a block containing a repeating unit represented by the formula (H).

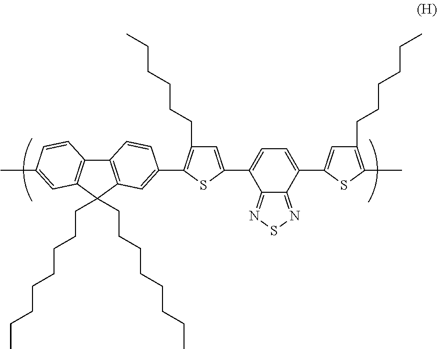

### Example 2

### Synthesis of Polymer Compound 2

Into a 200 ml separable flask, 0.65 g of methyltrioctylammonium chloride (trade name: aliquat336, manufactured by Aldrich, CH₃N[(CH₂)₇CH₃]₃Cl, density 0.884 g/ml, 25° C., trade name of Henkel Corporation), 1.5779 g of the compound (C), and 1.1454 g of the compound (E) were put, and replacement with nitrogen was carried out. Into this, 35 ml of toluene that had been degassed by bubbling with argon gas in advance was added and, after stirring for dissolution, the solution was further degassed by bubbling with argon gas for 40 minutes. Subsequently, the flask containing this solution was immersed into a bath and, after the temperature thereof was raised to 85° C., 1.6 mg of palladium acetate and 6.7 mg of tris-o-methoxyphenylphosphine were added into the solution. Then, while the temperature of the bath was being raised up to 105° C., 9.5 ml of a 17.5% aqueous solution of sodium carbonate was dropwise added over 6 minutes. After dropwise addition, the solution was stirred for 1.7 hours at a bath temperature of 105° C., and the reaction solution was cooled to room temperature. In the reaction solution, a polymer containing a repeating unit represented by the formula (G) is contained.

Next, 1.0877 g of the compound (C) and 0.9399 g of the compound (D) were added into the reaction solution. Into this, 15 ml of toluene that had been degassed by bubbling with argon gas in advance was added and, after stirring for dissolution, the solution was further degassed by bubbling with argon gas for 30 minutes. Into this solution, 1.3 mg of palladium acetate and 4.7 mg of tris-o-methoxyphenylphosphine were added. Then, while the temperature of the bath was being raised up to 105° C., 6.8 ml of a 17.5% aqueous solution of sodium carbonate was dropwise added over 5 minutes. After dropwise addition, the solution was stirred for 3 hours at a bath temperature of 105° C. After stirring, 50 ml of toluene that had been degassed by bubbling with argon gas in advance, 2.3 mg of palladium acetate, 8.8 mg of tris-o-methoxyphenylphosphine, and 0.305 g of phenylboric acid were added and stirred for about 8 hours at a bath temperature of 105° C. After an aqueous layer was removed from the reaction liquid, an aqueous solution obtained by dissolving 3.1 g of sodium N,N-diethyldithiocarbamate into 30 ml of water was added and stirred for 2 hours at a bath temperature of 85° C. Subsequently, 250 ml of toluene was added into this, and the reaction liquid was separated. After the organic phase was washed twice with 65 ml of water, twice with 65 ml of 3% acetic acid water, and twice with 65 ml of water, the resultant was diluted with the addition of 150 ml of toluene and dropwise added into 2500 ml of methanol so as to reprecipitate the polymer. After the precipitated polymer was filtered and dried under reduced pressure, the polymer was dissolved in 500 ml of toluene and passed through a silica gel-alumina column. The obtained toluene solution was dropwise added into 3000 ml of methanol so as to reprecipitate the polymer. The polymer was filtered and dried under reduced pressure to obtain 3.00 g of the polymer compound 2. The weight-average molecular weight of the obtained polymer compound 2 as converted in terms of polystyrene was 257,000, and the number-average molecular weight was 87,000.

The polymer compound 2 has a block containing a repeating unit represented by the formula (G) and a block containing a repeating unit represented by the formula (H).

### Synthesis Example 1

### Synthesis of Polymer Compound 3

Into a reaction container, 1.061 g of the compound (C), 1.253 g of the compound (D), 0.31 g of methyltrioctylammonium chloride (trade name: aliquat336, manufactured by Aldrich, CH₃N[(CH₂)₇CH₃]₃Cl, density 0.884 g/ml, 25° C., trade name of Henkel Corporation), and 3.2 mg of dichlorobis(triphenylphosphine)palladium (II) were put, and replacement with argon gas was carried out in the reaction container. Into this reaction container, 45 ml of toluene that had been degassed by bubbling with argon gas in advance was added. Next, into this solution, 10 ml of a 16.7 wt % aqueous solution of sodium carbonate that had been degassed by bubbling with argon gas in advance was dropwise added and refluxed for 12 hours. Next, the reaction solution was cooled to room temperature and, after a mixed solution of 0.1 g of phenylboric acid/0.5 ml of tetrahydrofuran was added, the resultant was refluxed for 2 hours. Here, the reaction was carried out in an argon gas atmosphere.

After the reaction was finished, the reaction solution was cooled to room temperature, and then 60 g of toluene was added into this reaction solution. This reaction solution was left to stand still, and the separated toluene solution was collected. Next, this toluene solution was filtered so as to remove insoluble substances. Next, this toluene solution was passed through an alumina column and purified. Next, this toluene solution was poured into methanol and reprecipitated, and the produced precipitate was collected. Next, this precipitate was dried under reduced pressure, and then dissolved in toluene again. Next, after this toluene solution was filtered, this toluene solution was passed through an alumina column and purified. Next, this toluene solution was poured into methanol and reprecipitated, and the produced precipitate was collected. After this precipitate was washed with methanol, this precipitate was dried under reduced pressure, so as to obtain 0.68 g of a polymer (hereafter, this polymer will be referred to as the “polymer compound 3”). The weight-average molecular weight of the polymer compound 3 as converted in terms of polystyrene was 1.2×10⁵, and the number-average molecular weight was 5.9×10⁴.

The polymer compound 3 is made of a repeating unit represented by the formula (H).

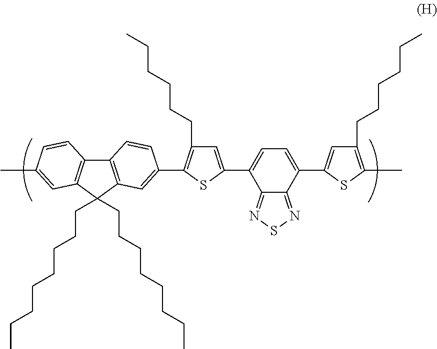

### Synthesis Example 2

### Synthesis of Polymer Compound 4

Into a 1 L three-neck flask replaced with nitrogen, 18.55 g (34.98 mmol) of the compound (C), 11.72 g (36.17 mmol) of the compound (E), 4.00 g of methyltrioctylammonium chloride (trade name: aliquat336, manufactured by Aldrich, CH₃N[(CH₂)₇CH₃]₃Cl, density 0.884 g/ml (25° C.)), 0.023 g of Pd(PPh₃)₂Cl₂, and 300 ml of toluene were put, and the mixture was heated to 55° C. and stirred. Into this, 60 ml of a 2 mol/l aqueous solution of sodium carbonate was dropwise added. After the dropwise addition was finished, the temperature was raised to 95° C., and the reaction was carried out for 24 hours. Into the obtained solution, 2.0 g of phenylboronic acid, 40 ml of tetrahydrofuran, and 0.023 g of Pd(PPh₃)₂Cl₂ were added, and the reaction was further carried out for 24 hours. The obtained solution was diluted with 400 ml of toluene and, after the organic phase was extracted, the resultant was washed three times with 600 ml of hot water. Into the obtained solution, 300 ml of a 7.5 wt % aqueous solution of sodium diethyldithiocarbamate trihydrate was added, and stirred overnight at 80° C. After the aqueous phase was removed by being left to stand still, the resultant was washed with 600 ml of 2 wt % acetic acid, and then was washed twice with 600 ml of hot water. Into the obtained solution, 500 ml of toluene was added, and the resultant was added into 3 L of methanol in two steps and reprecipitated. The polymer collected by filtering the obtained solution was washed with 1 L of methanol, and dried in vacuum overnight at 60° C. The obtained polymer was dissolved in 2 L of hot toluene, and passed through a column using Celite, silica gel, and basic alumina. The column was washed with 800 ml of hot toluene, and the obtained solution was concentrated down to 1300 ml. The resultant was added into 3 L of methanol in two steps so as to reprecipitate the polymer, and the obtained precipitate was filtered to collect a polymer. This polymer was washed successively with methanol, acetone, and methanol (each 500 ml), and dried in vacuum at 60° C. to obtain a polymer compound 4. The number-average molecular weight Mn of the polymer compound 4 as converted in terms of polystyrene was 2.2×10⁴, and the weight-average molecular weight Mw as converted in terms of polystyrene was 4.4×10⁴.

The polymer compound 4 contains a repeating unit represented by the formula (G).

### Example 3

### Fabrication and Evaluation of Organic Thin Film Solar Cell

As an electron donor, the polymer compound 1 was dissolved in xylene at a concentration of 0.75% (wt %). Thereafter, triple weight of PCBM (Phenyl C61-butyric acid methyl ester, manufactured by Frontier Carbon Corporation, trade name: E100) relative to the weight of the polymer compound 1 was mixed into the solution as an electron acceptor. Subsequently, the resultant was filtered with a Teflon (registered trade name) filter of 1.0 μm, so as to fabricate an application solution.

A glass substrate to which an ITO film had been attached to a thickness of 150 nm by the sputtering method was subjected to ozone UV treatment so as to perform surface treatment. Next, the application liquid was applied by spin coating, so as to obtain an active layer (having a film thickness of about 100 nm) of an organic thin film solar cell. Thereafter, by a vacuum vapor deposition apparatus, lithium fluoride was vapor-deposited to 4 nm, and then Al was vapor-deposited to 100 nm. The degree of vacuum at the time of vapor deposition was all 1 to 9×10⁻³ Pa. The shape of the obtained organic thin film solar cell was a square of 2 mm×2 mm.

The photoelectric conversion efficiency of the obtained organic thin film solar cell was measured by a solar simulator (manufactured by Bunkoh-Keiki Co., Ltd., trade name: OTENTO-SUNII: AM1.5G filter, radiation illuminance 100 mW/cm²). The measurement result is shown in Table 1.

### Example 4

An organic photoelectric converter was fabricated by a method similar to that of Example 3 except that the polymer compound 2 was used in place of the polymer compound 1, and the photoelectric conversion efficiency was measured. The measurement result is shown in Table 1.

### Comparative Example 1

An organic photoelectric converter was fabricated by a method similar to that of Example 3 except that the polymer compound 3 was used in place of the polymer compound 1, and the photoelectric conversion efficiency was measured. The measurement result is shown in Table 1.

### Comparative Example 2

An organic photoelectric converter was fabricated by a method similar to that of Example 3 except that the polymer compound 4 was used in place of the polymer compound 1, and the photoelectric conversion efficiency was measured. The measurement result is shown in Table 1.

TABLE 1

| | | Photoelectric |
|---|---|---|
| | | conversion |
| | Polymer | efficiency (%) |
| Example 3 | polymer compound 1 | 2.5 |
| Example 4 | polymer compound 2 | 3.0 |
| Comparative Example 1 | polymer compound 3 | 0.9 |
| Comparative Example 2 | polymer compound 4 | 0.4 |

### Evaluation

As will be understood from Table 1, the organic thin film solar cells (Examples 3 and 4) formed by using the polymer compounds 1 and 2 containing a repeating unit represented by the formula (1) and a repeating unit represented by the formula (2) showed a higher photoelectric conversion efficiency as compared with the organic thin film solar cells (Comparative Examples 1 and 2) formed by using polymer compounds other the polymer compounds of the present invention.

### INDUSTRIAL APPLICABILITY

By using the polymer compound of the present invention, an organic photoelectric converter exhibiting an excellent photoelectric conversion efficiency can be produced. Therefore, the present invention is industrially extremely useful.

1. A polymer compound comprising a repeating unit represented by the formula (1) and a repeating unit represented by the formula (2): 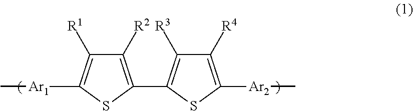
wherein Ar₁ and Ar₂ each independently represent an arylene group or a group represented by the formula (3); R¹, R², R³, and R⁴ each independently represent a hydrogen atom, an alkyl group, an alkoxy group, or an aryl group; and a hydrogen atom contained in these groups may be substituted by a fluorine atom: 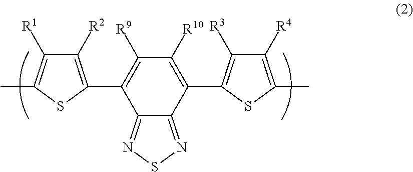
wherein R⁵, R⁶, R⁷, R⁸, R⁹, and R¹⁰ each independently represent a hydrogen atom, an alkyl group, an alkoxy group, or an aryl group; and a hydrogen atom contained in these groups may be substituted by a fluorine atom: 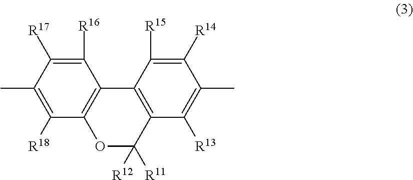
wherein R¹¹, R¹², R¹³, R¹⁴, R¹⁵, R¹⁶, R¹⁷ and R¹⁸ each independently represent a hydrogen atom, an alkyl group, an alkoxy group, or an aryl group; and a hydrogen atom contained in these groups may be substituted by a fluorine atom.

2. The polymer compound according to claim 1, wherein the arylene group is a group represented by the formula (4) or a group represented by the following formula (5): 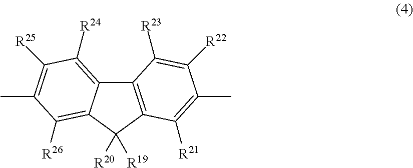
wherein R¹⁹, R²⁰, R²¹, R²², R²³, R²⁴, R²⁵, and R²⁶ each independently represent a hydrogen atom, an alkyl group, an alkoxy group, or an aryl group; and a hydrogen atom contained in these groups may be substituted by a fluorine atom: 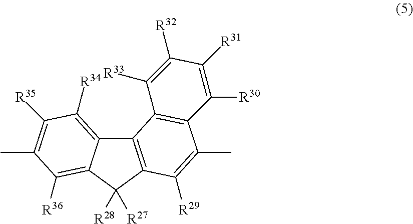
wherein R²⁷, R²⁸, R²⁹, R³⁰, R³¹, R³², R³³, R³⁴, R³⁵, and R³⁶ each independently represent a hydrogen atom, an alkyl group, an alkoxy group, or an aryl group; and a hydrogen atom contained in these groups may be substituted by a fluorine atom.

3. The polymer compound according to claim 1, which is a block copolymer.

4. The polymer compound according to claim 1, which comprises a block having a repeating unit represented by the formula (1).

5. The polymer compound according to claim 1, which comprises a block having one or more kinds of repeating units selected from the group consisting of a repeating unit represented by the formula (6), a repeating unit represented by the formula (7), and a repeating unit represented by the formula (8): 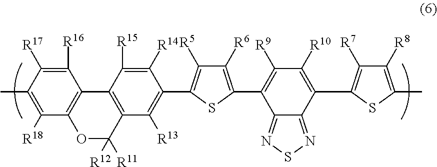
wherein R⁵, R⁶, R⁷, R⁸, R⁹, R¹⁰, R¹¹, R¹², R¹³, R¹⁴, R¹⁵, R¹⁶, R¹⁷, and R¹⁸ represent the same meanings as described above: 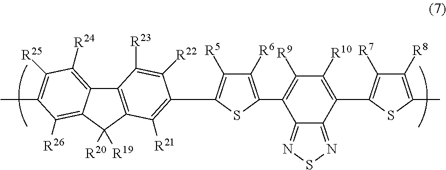
wherein R⁵, R⁶, R⁷, R⁸, R⁹, R¹⁰, R¹⁹, R²⁰, R²¹, R²², R²³, R²⁴, R²⁵, and R²⁶ represent the same meanings as described above: 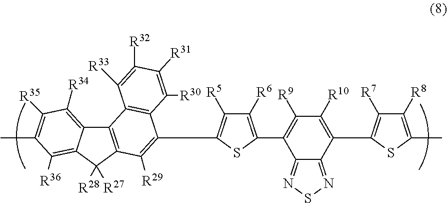
wherein R⁵, R⁶, R⁷, R⁸, R⁹, R¹⁰, R²⁷, R²⁸, R²⁹, R³⁰, R³¹, R³², R³³, R³⁴, R³⁵, and R³⁶ represent the same meanings as described above.

6. The polymer compound according to claim 1, wherein the formula (1) is a repeating unit represented by the formula (9): 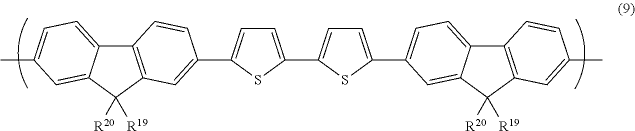
wherein R¹⁹ and R²⁰ represent the same meanings as described above; and the plurality of groups R¹⁹ and R²⁰ may each be the same or different.

7. An organic photoelectric converter comprising an organic layer containing the polymer compound according to claim 1.

8. An organic photoelectric converter comprising a pair of electrodes at least one of which is transparent or semitransparent, and a first organic layer containing the polymer compound according to claim 1 and a second organic layer containing an electron-donating compound disposed adjacent to the first organic layer between the electrodes.

9. An organic photoelectric converter comprising a pair of electrodes at least one of which is transparent or semitransparent, and a first organic layer containing an electron-accepting compound and a second organic layer containing the polymer compound according to claim 1 disposed adjacent to the first organic layer between the electrodes.

10. An organic photoelectric converter comprising a pair of electrodes at least one of which is transparent or semitransparent and an organic layer containing the polymer compound according to claim 1 and an electron-donating compound between the electrodes.

11. An organic photoelectric converter comprising a pair of electrodes at least one of which is transparent or semitransparent and an organic layer containing an electron-accepting compound and the polymer compound according to claim 1 between the electrodes.

12. The organic photoelectric converter according to claim 11, wherein the electron-accepting compound is a fullerene derivative.
